(19) United States
(12) Patent Application Publication
(10) Pub. No.: US 2026/0371637 A1
(43) Pub. Date: Nov. 19, 2026

(54) NITRIDE SEMICONDUCTOR DEVICE

(71) Applicant: ROHM CO., LTD., Kyoto-shi (JP)

(72) Inventors: Hirotaka OTAKE, Kyoto-shi (JP); Shoei KASHIWAGI, Kyoto-shi (JP); Masaki TAKAOKA, Kyoto-shi (JP)

(73) Assignee: ROHM CO., LTD., Kyoto-shi (JP)

(21) Appl. No.: 19/670,066

(22) Filed: May 7, 2026

(30) Foreign Application Priority Data
May 13, 2025 (JP) 2025-080678

(51) Int. Cl. H10D 30/47; H10D 30/01; H10D 62/85; H10D 64/00

(52) U.S. Cl. CPC H10D 30/475; H10D 30/015; H10D 62/8503; H10D 64/112

(57) ABSTRACT

A nitride semiconductor device includes a substrate, an electron transit layer, an electron supply layer, a gate structure, a first insulating film, a source electrode, a drain electrode, a first field plate electrode, and a first insulator. The gate structure includes a gate layer, and a gate electrode formed on the gate layer. The first insulating film covers the electron supply layer and the gate structure. The source electrode and the drain electrode are in contact with the electron supply layer. The first field plate electrode is formed on the first insulating film. The first field plate electrode and a side wall of the gate structure, which is located relatively close to the drain electrode, face each other with the first insulating film and the first insulator located in between.

### CROSS-REFERENCE TO RELATED APPLICATION

This application is based upon and claims the benefit of priority from Japanese Patent Application No. 2025-080678, filed on May 13, 2025, the entire contents of which are incorporated herein by reference.

### BACKGROUND

The following description relates to a nitride semiconductor device.

JP2017-73506A describes an example of a high-electron-mobility transistor (HEMT) product that uses a group III nitride semiconductor (hereafter, simply “nitride semiconductor”), such as gallium nitride (GaN).

This type of nitride semiconductor device may have a structure including an electron transit layer, an electron supply layer, a gate layer, a gate electrode, and a passivation layer. The electron supply layer is formed on the electron transit layer and has a larger band gap than the electron transit layer. The gate layer is formed on the electron transit layer and contains an acceptor impurity. The gate electrode is formed on the gate layer. The passivation layer covers the electron supply layer, the gate layer, and the gate electrode. This nitride semiconductor device may further include a field plate electrode integrated with a source electrode. The field plate electrode extends from the source electrode toward a drain electrode over the gate layer and the gate electrode.

### BRIEF DESCRIPTION OF THE DRAWINGS

FIG. 1 is a schematic plan view of an exemplary nitride semiconductor device in accordance with an embodiment.

FIG. 2 is an enlarged schematic plan view showing part of the internal structure of the nitride semiconductor device shown in FIG. 1.

FIG. 3 is a schematic plan view of the internal structure shown in FIG. 2, on which wiring layers are placed.

FIG. 4 is a schematic cross-sectional view of the nitride semiconductor device 10 taken along line F4-F4 shown in FIG. 2.

FIG. 5 is a partially enlarged view of the cross-sectional structure shown in FIG. 4.

FIG. 6 is a schematic cross-sectional view illustrating an exemplary manufacturing step of the nitride semiconductor device shown in FIG. 4.

FIG. 7 is a schematic cross-sectional view illustrating an exemplary manufacturing step following the step of FIG. 6.

FIG. 8 is a schematic cross-sectional view illustrating an exemplary manufacturing step following the step of FIG. 7.

FIG. 9 is a schematic cross-sectional view illustrating an exemplary manufacturing step following the step of FIG. 8.

FIG. 10 is a schematic cross-sectional view illustrating an exemplary manufacturing step following the step of FIG. 9.

FIG. 11 is a schematic cross-sectional view illustrating an exemplary manufacturing step following the step of FIG. 10.

FIG. 12 is a schematic cross-sectional view illustrating an exemplary manufacturing step following the step of FIG. 11.

FIG. 13 is a schematic cross-sectional view illustrating an exemplary manufacturing step following the step of FIG. 12.

FIG. 14 is a schematic cross-sectional view illustrating an exemplary manufacturing step following the step of FIG. 13.

FIG. 15 is a schematic cross-sectional view illustrating an exemplary manufacturing step following the step of FIG. 14.

FIG. 16 is a schematic cross-sectional view illustrating an exemplary manufacturing step following the step of FIG. 15.

FIG. 17 is a schematic cross-sectional view illustrating an exemplary manufacturing step following the step of FIG. 16.

FIG. 18 is a schematic cross-sectional view illustrating an exemplary manufacturing step following the step of FIG. 17.

FIG. 19 is a schematic cross-sectional view illustrating an exemplary manufacturing step following the step of FIG. 18.

FIG. 20 is a schematic cross-sectional view illustrating an exemplary manufacturing step following the step of FIG. 19.

FIG. 21 is a schematic cross-sectional view illustrating an exemplary manufacturing step following the step of FIG. 20.

FIG. 22 is a schematic cross-sectional view illustrating an exemplary manufacturing step following the step of FIG. 21.

FIG. 23 is a schematic cross-sectional view illustrating an exemplary manufacturing step following the step of FIG. 22.

FIG. 24 is a schematic cross-sectional view illustrating a manufacturing step of a comparative structure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a nitride semiconductor device according to the present disclosure will now be described with reference to the accompanying drawings. Elements in the drawings may not be drawn to scale for simplicity and clarity of illustration. In the cross-sectional drawings, hatching lines may not be shown to facilitate understanding. The accompanying drawings merely illustrate exemplary embodiments of the present disclosure and are not intended to limit the present disclosure.

Terms such as “first”, “second”, and “third” in this disclosure are used to distinguish elements of a subject and are not used for ordinal purposes. In this specification, the phrase “at least one of” means “one or more” of desired options. In an example, the phrase “at least one of” as used in this disclosure means “only one of two options” or “both of two options” if the number of options is two. In another example, the phrase “at least one of” as used in this disclosure means “only one of the options” or “any combination of two or more of the options” if the number of options is three or more.

This detailed description includes exemplary embodiments of devices, systems, and methods in accordance with the present disclosure. The present description is illustrative and is not intended to limit the embodiments of the present disclosure or application and use of the embodiments.

### Overall Structure of Nitride Semiconductor Device

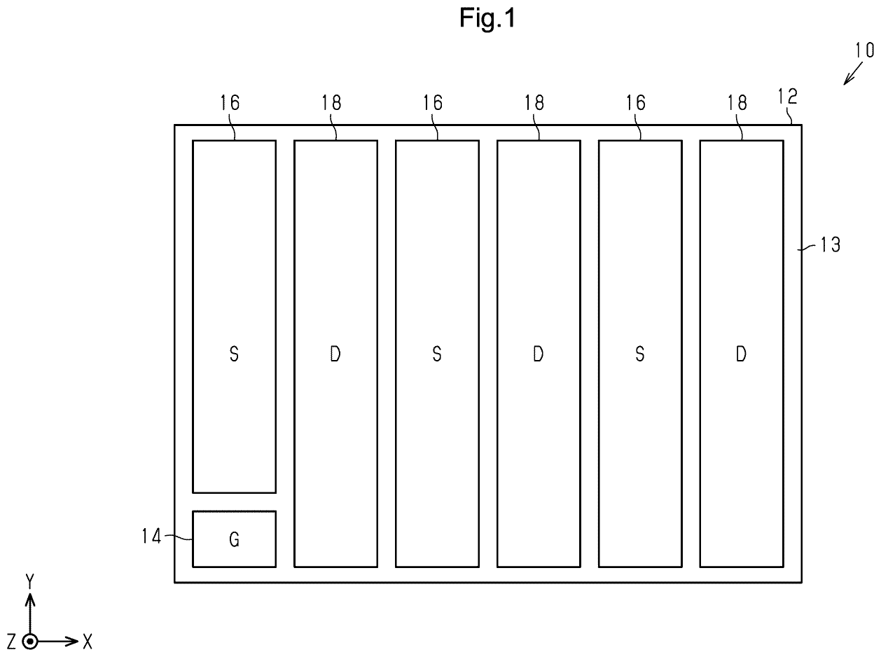

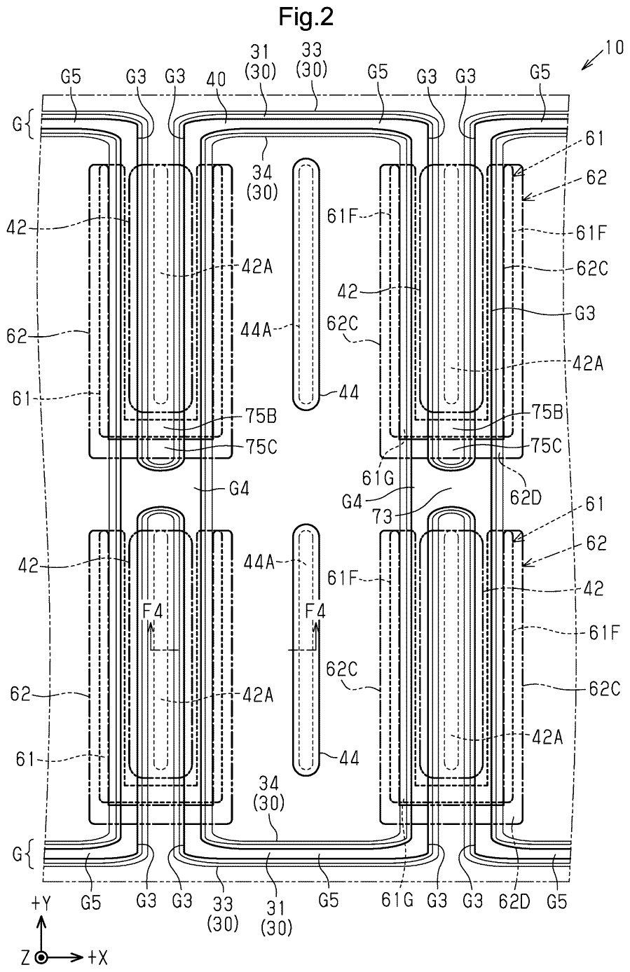

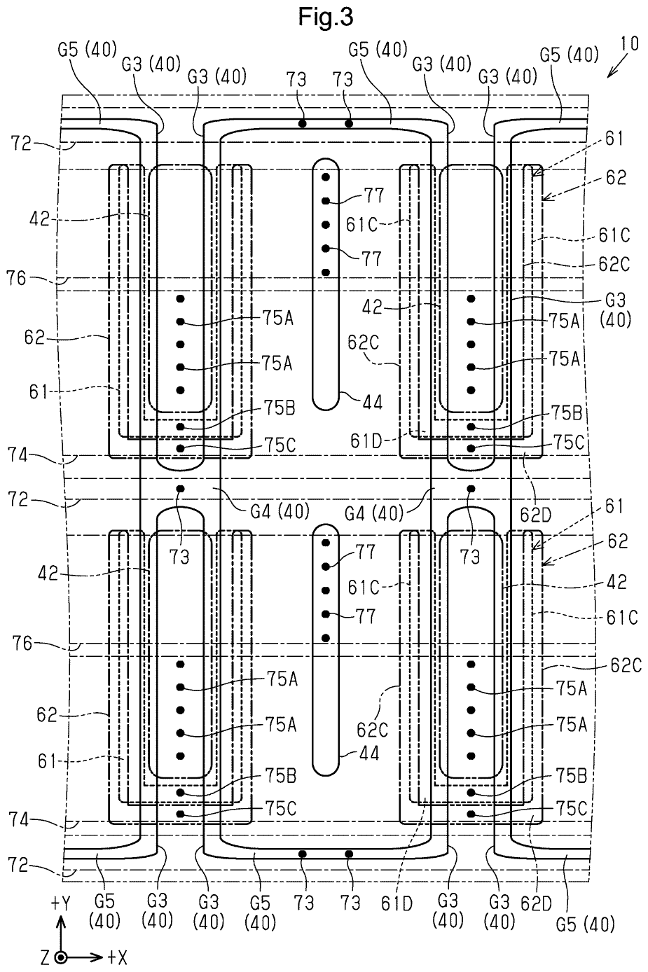

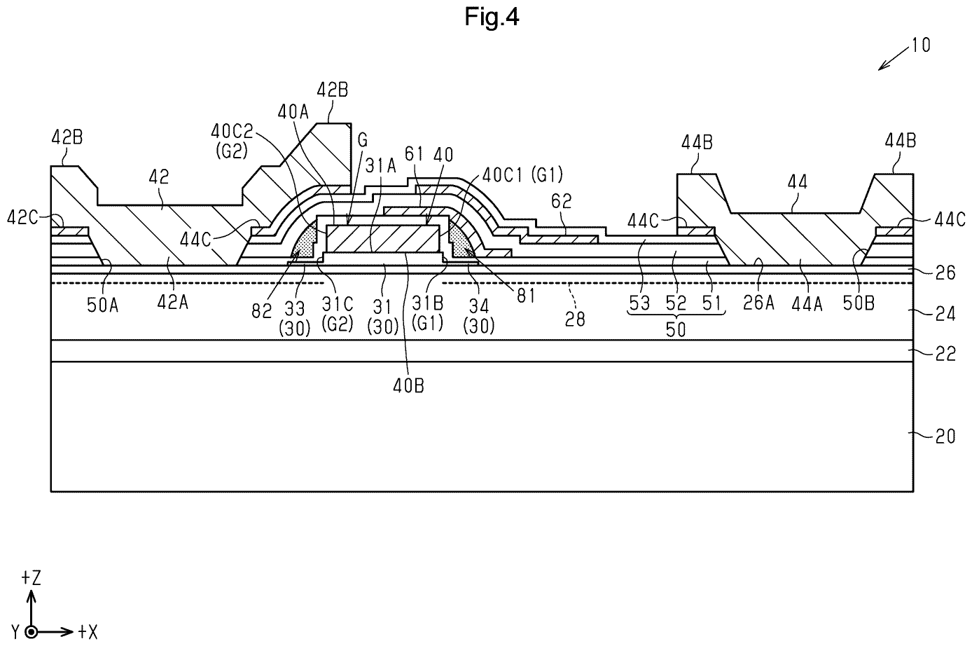

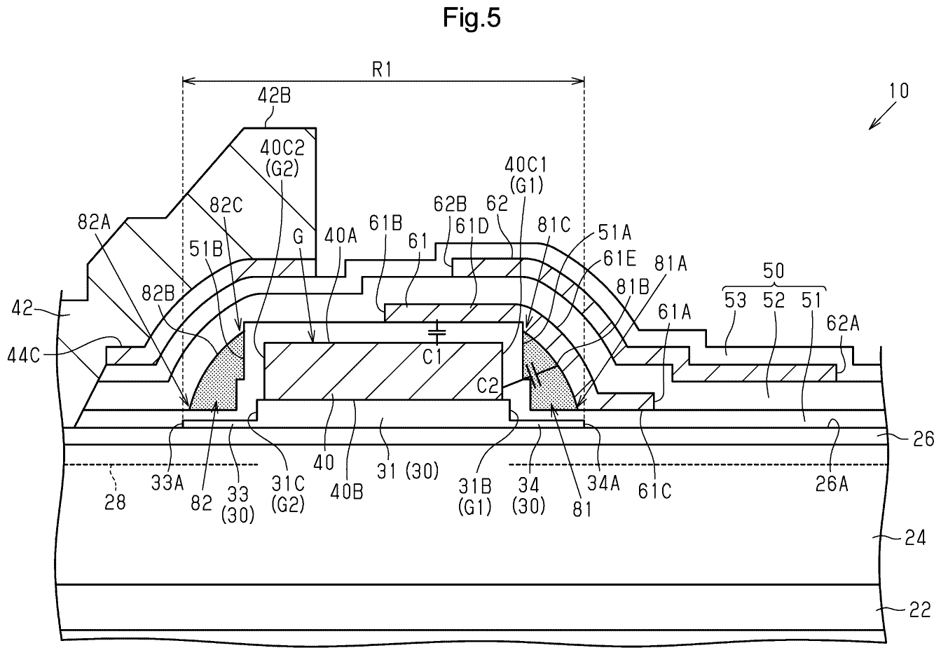

The overall structure of a nitride semiconductor device 10 in accordance with an embodiment will now be described with reference to FIGS. 1 to 5. FIG. 1 is a schematic plan view of an exemplary nitride semiconductor device 10 in accordance with the embodiment. FIG. 2 is an enlarged schematic plan view showing part of the internal structure of the nitride semiconductor device 10 shown in FIG. 1. FIG. 3 is a schematic plan view of the internal structure shown in FIG. 2, on which various types of wiring layers are placed. FIG. 4 is a schematic cross-sectional view of the nitride semiconductor device 10 taken along line F4-F4 shown in FIG. 2. FIG. 5 is a partially enlarged view of the cross-sectional structure shown in FIG. 4.

As shown in FIG. 1, the nitride semiconductor device 10 includes a chip body 12. The chip body 12 is, for example, rectangular and flat. FIG. 1 and the other figures indicate X, Y, and Z axes that are orthogonal to one another. The Z-axis direction is orthogonal to a main surface (upper surface 13 in FIG. 1) of the chip body 12. The term “plan view” as used in the present disclosure refers to a view of the nitride semiconductor device 10 taken from above in the Z-axis direction, unless otherwise specified. The X-axis direction serves as a first direction.

The nitride semiconductor device 10 includes at least one gate pad 14, at least one source pad 16, and at least one drain pad 18. In the example shown in FIG. 1, the nitride semiconductor device 10 includes a single gate pad 14, multiple source pads 16, and multiple drain pads 18. The gate pad 14, the source pads 16, and the drain pads 18 are arranged on the upper surface 13 of the chip body 12. These pads 14, 16, 18 are configured to act as external connection terminals of the nitride semiconductor device 10.

The gate pad 14, the source pads 16, and the drain pads 18 are each, for example, rectangular in plan view. The gate pad 14 may be located, for example, at a corner of the upper surface 13. The source pads 16 and the drain pads 18 each extend in the Y-axis direction in plan view. The source pads 16 and the drain pads 18 are alternately arranged in the X-axis direction, which is orthogonal to the Y-axis direction. In other words, in plan view, the source pads 16 and the drain pads 18 each extend in a direction (Y-axis direction) that is orthogonal to the direction (X-axis direction) in which the pads 16 and 18 are arranged next to each other. The planar shapes of the gate pad 14, the source pads 16, and the drain pads 18 may be changed. Also, the arrangement of the gate pad 14, the source pads 16, and the drain pads 18 may be changed.

As shown in FIG. 4, the nitride semiconductor device 10 is configured to be a high-electron-mobility transistor (HEMT) that uses a nitride semiconductor. The nitride semiconductor device 10 includes a substrate 20, a buffer layer 22 formed on the substrate 20, an electron transit layer 24 formed on the buffer layer 22, and an electron supply layer 26 formed on the electron transit layer 24.

The substrate 20 is, for example, a semiconductor substrate. The substrate 20 may be composed of silicon (Si), silicon carbide (SiC), gallium nitride (GaN), sapphire, or any other substrate material. In an example, the substrate 20 is a Si substrate. The substrate 20 may have a thickness, for example, between 200 μm and 1500 μm, inclusive. The Z-axis direction coincides with the thickness-wise direction of the substrate 20.

The buffer layer 22 may be composed of any material that reduces wafer warping or cracking, which may be caused by a mismatch in thermal expansion coefficient between the substrate 20 and the electron transit layer 24. The buffer layer 22 may include one or more nitride semiconductor layers. The buffer layer 22 includes, for example, at least one of an aluminum nitride (AlN) layer, an aluminum gallium nitride (AlGaN) layer, and a graded AlGaN layer having different aluminum (Al) compositions. In an example, the buffer layer 22 may be composed of a single AlN layer, a single AlGaN layer, a layer having an AlGaN/GaN superlattice structure, a layer having an AlN/AlGaN superlattice structure, or a layer having an AlN/GaN superlattice structure.

In an example, the buffer layer 22 may include a first buffer layer of an AlN layer formed on the substrate 20, and a second buffer layer of an AlGaN layer formed on the AlN layer. In an example, the first buffer layer may be an AlN layer having a thickness of 100 nm to 300 nm, and the second buffer layer may include multiple AlGaN layers of different compositions, each having a thickness of 100 nm to 300 nm. To reduce leakage current in the buffer layer 22, the buffer layer 22 may be partially doped with an impurity so that the buffer layer 22 becomes semi-insulative. In this case, the impurity may be carbon (C) or iron (Fe), and the impurity may have a concentration of, for example, 4×10¹⁶ cm⁻³ or higher.

The electron transit layer 24 is composed of a nitride semiconductor. The electron transit layer 24 may be, for example, a GaN layer. The electron transit layer 24 may have a thickness, for example, between 0.5 μm and 2 μm, inclusive. The electron transit layer 24 may include one or more nitride semiconductor layers. To reduce leakage current in the electron transit layer 24, the electron transit layer 24 may be partially doped with an impurity so that the electron transit layer 24 becomes semi-insulative, except for the outermost part. In this case, the impurity may be carbon (C), and the carbon (impurity) may have a peak concentration of, for example, 4×10¹⁶ cm⁻³ or higher.

The electron supply layer 26 is composed of a nitride semiconductor having a larger band gap than the electron transit layer 24. The electron supply layer 26 may be, for example, an AlGaN layer. The bandgap becomes larger as the Al composition increases. Therefore, the electron supply layer 26, which is an AlGaN layer, has a larger band gap than the electron transit layer 24, which is a GaN layer. In an example, the electron supply layer 26 is composed of AlₓGa₁₋ₓN having an Al composition ratio of “x”. In this case, the Al composition ratio x satisfies 0.1<x <0.4; more preferably, 0.1<x <0.3. The electron supply layer 26 may have a thickness, for example, between 5 nm and 20 nm, inclusive.

The electron transit layer 24 and the electron supply layer 26 have different lattice constants in a bulk region. Therefore, the nitride semiconductor (e.g., GaN) of the electron transit layer 24 and the nitride semiconductor (e.g., AlGaN) of the electron supply layer 26 form a lattice-mismatched heterojunction. The spontaneous polarization of the electron transit layer 24 and the electron supply layer 26 and the piezoelectric polarization resulting from the compression stress received by the heterojunction of the electron transit layer 24 cause the energy level of the conduction band of the electron transit layer 24 to be lower than the Fermi level in the proximity of the heterojunction interface between the electron transit layer 24 and the electron supply layer 26. Accordingly, a two-dimensional electron gas (2DEG) 28 is spread in the electron transit layer 24 at a position proximate (e.g., approximately a few nanometers) to the heterojunction interface of the electron transit layer 24 and the electron supply layer 26.

The nitride semiconductor device 10 includes a gate structure G. The gate structure G includes a gate layer 30 formed on part of the electron supply layer 26, and a gate electrode 40 formed on the gate layer 30. The gate structure G will be described in detail later.

The gate layer 30 is composed of a nitride semiconductor. In an example, the gate layer 30 has a smaller band gap than the electron supply layer 26, and is composed of a nitride semiconductor containing an acceptor impurity. In an example, the gate layer 30 is a GaN (p-type GaN) layer doped with an acceptor impurity. The acceptor impurity may be at least one of magnesium (Mg), zinc (Zn), and C. The acceptor impurity in the gate layer 30 may have a maximum concentration, for example, between 1×10¹⁸ cm⁻³ and 1×10²⁰ cm⁻³, inclusive.

The gate electrode 40 includes one or more metal layers. In an example, the gate electrode 40 may be a titanium nitride (TiN) layer. In another example, the gate electrode 40 may include a first metal layer composed of Ti, and a second metal layer formed on the first metal layer and composed of TiN. The gate electrode 40 may be composed of a material that forms a Schottky junction with the gate layer 30. An example of such a material is TiN. The gate electrode 40 may have a thickness, for example, between 50 nm and 200 nm, inclusive.

The nitride semiconductor device 10 includes an insulating film 50. The insulating film 50 covers the electron supply layer 26 and the gate structure G (gate layer 30 and gate electrode 40). The insulating film 50 will be described in detail later. The insulating film 50 includes a source opening 50A and a drain opening 50B that expose parts of an upper surface 26A of the electron supply layer 26.

The nitride semiconductor device 10 includes a source electrode 42 formed in the source opening 50A, and a drain electrode 44 formed in the drain opening 50B. The source electrode 42 includes a source contact 42A that is in contact with the electron supply layer 26 with the source opening 50A located in between. The drain electrode 44 includes a drain contact 44A that is in contact with the electron supply layer 26 with the drain opening 50B located in between.

In an example, the source electrode 42 may include a source extension 42B formed integrally with the source contact 42A. The source extension 42B is disposed on the insulating film 50 and extends from the source contact 42A in the X-axis direction. An example of the source extension 42B, which extends toward the gate electrode 40 in the X-axis direction, covers part of the gate structure G. In an example, the drain electrode 44 may include a drain extension 44B formed integrally with the drain contact 44A. The drain extension 44B is disposed on the insulating film 50 and extends from the drain contact 44A in the X-axis direction.

The insulating film 50 includes a first insulating film 51, a second insulating film 52, and a third insulating film 53, which will be described later, stacked in the Z-axis direction. Accordingly, the source extension 42B and the drain extension 44B are disposed on the first insulating film 51.

The source electrode 42 and the drain electrode 44 each include one or more metal layers. In an example, the source electrode 42 and the drain electrode 44 may each be composed of one of, or any combination of, Ti, TiN, Al, aluminum silicon copper (AlSiCu), and aluminum copper (AlCu). In an example, the source electrode 42 and the drain electrode 44 each include a first metal layer in contact with the electron supply layer 26, a second metal layer formed on the first metal layer, a third metal layer formed on the second metal layer, and a fourth metal layer formed on the third metal layer. The first metal layer is, for example, a Ti layer. The second metal layer is, for example, an Al layer. The third metal layer is, for example, a Ti layer. The fourth metal layer is, for example, a TiN layer.

An example of the source electrode 42 may include a barrier metal layer 42C formed between the insulating film 50 and the source extension 42B. An example of the drain electrode 44 may include a barrier metal layer 44C formed between the insulating film 50 and the drain extension 44B. The barrier metal layer 42C and the barrier metal layer 44C are, for example, TiN layers.

The source contact 42A of the source electrode 42 fills the source opening 50A. The source contact 42A forms an ohmic contact with the 2DEG 28 that is present immediately below the electron supply layer 26 in the source opening 50A. The drain contact 44A of the drain electrode 44 fills the drain opening 50B. The drain contact 44A forms an ohmic contact with the 2DEG 28 that is present immediately below the electron supply layer 26 in the drain opening 50B. Although not shown in the drawings, the substrate 20 is electrically connected to the source electrode 42. Accordingly, a voltage having the same potential as the source electrode 42 is applied to the substrate 20.

In a structure in which the gate layer 30 is composed of a nitride semiconductor containing an acceptor impurity, the 2DEG 28 is depleted in a region underneath the gate layer 30 in a zero-bias state in which no voltage is applied to the gate electrode 40, such that the conduction path (channel) is interrupted. Therefore, the HEMT is a normally-off type and has a gate threshold voltage that is positive.

The gate structure will now be described in detail.

The structure of the gate structure G will be described in detail with reference to FIGS. 4 and 5.

The gate layer 30 is located between the source contact 42A and the drain contact 44A in the X-axis direction. The gate layer 30 is spaced apart from both of the source contact 42A and the drain contact 44A. In an example, the gate layer 30 is located closer to the source contact 42A than to the drain contact 44A.

The gate layer 30 may include a ridge 31, a source-side extension 33, and a drain-side extension 34. The ridge 31 is in contact with the electron supply layer 26 and includes an upper surface 31A. The source-side extension 33 and the drain-side extension 34 are in contact with the electron supply layer 26 and extend outward from the ridge 31 in plan view. The source-side extension 33 and the drain-side extension 34 are thinner than the ridge 31.

Since the source-side extension 33 and the drain-side extension 34 are thinner than the ridge 31, the upper surface of the source-side extension 33 and the upper surface of the drain-side extension 34 are located downward from the upper surface 31A of the ridge 31 in the Z-axis direction. The ridge 31 includes a first side surface 31B and a second side surface 31C that connect the upper surface 31A of the ridge 31 to the source-side extension 33 and the drain-side extension 34. The first side surface 31B is located relatively close to the drain electrode 44 in the X-axis direction. The second side surface 31C is located relatively close to the source electrode 42 in the X-axis direction.

The source-side extension 33 extends from the ridge 31 toward the source opening 50A. In plan view, the source-side extension 33 covers part of the surface of the electron supply layer 26, which is located between the ridge 31 and the source opening 50A. The source-side extension 33 does not reach the source contact 42A, which is embedded in the source opening 50A.

The drain-side extension 34 extends from the ridge 31 toward the drain opening 50B. In plan view, the drain-side extension 34 covers part of the surface of the electron supply layer 26, which is located between the ridge 31 and the drain opening 50B. The drain-side extension 34 does not reach the drain contact 44A, which is embedded in the drain opening 50B.

The ridge 31 is located between the source-side extension 33 and the drain-side extension 34, and is formed integrally with the source-side extension 33 and the drain-side extension 34. Because of the source-side extension 33 and the drain-side extension 34, the bottom surface of the gate layer 30 is larger than its upper surface 31A. In an example, in plan view, the drain-side extension 34 may extend from the ridge 31 farther outward than the source-side extension 33. That is, the drain-side extension 34 may be longer than the source-side extension 33 in the X-axis direction. The source-side extension 33 may have a length, for example, between 0.2 μm and 0.3 μm, inclusive, in the X-axis direction. The drain-side extension 34 may have a length, for example, between 0.2 μm and 0.6 μm, inclusive, in the X-axis direction.

The ridge 31 is a relatively thick part of the gate layer 30. The ridge 31 may have a thickness, for example, between 80 nm and 150 nm, inclusive. In an example, the ridge 31 may have a thickness greater than 110 nm. The source-side extension 33 and the drain-side extension 34 are both thinner than the ridge 31. In an example, the source-side extension 33 and the drain-side extension 34 may each have a thickness that is one-half of, or less than or equal to one-half of, the thickness of the ridge 31.

The gate electrode 40 is disposed on the upper surface 31A of the ridge 31. The gate electrode 40 is in contact with the upper surface 31A of the ridge 31. The gate electrode 40 may have a cross-sectional shape that is rectangular, trapezoidal, or the like.

The lower surface of the gate electrode 40 is in contact with the ridge 31 of the gate layer 30. The gate electrode 40 includes a first side surface 40C1 and a second side surface 40C2 that connect an upper surface 40A and a lower surface 40B of the gate electrode 40.

The gate structure G includes a first side wall G1 located relatively close to the drain electrode 44, and a second side wall G2 located relatively close to the source electrode 42. The first side wall G1 is a side wall of the gate structure G, which is located relatively close to the drain electrode 44. The first side wall G1 includes the first side surface 40C1 of the gate electrode 40 and the first side surface 31B of the ridge 31 of the gate layer 30. The second side wall G2 is a side wall of the gate structure G, which is located relatively close to the source electrode 42. The second side wall G2 includes the second side surface 40C2 of the gate electrode 40 and the second side surface 31C of the ridge 31 of the gate layer 30.

### Detailed Structure of Insulating Film

The structure of the insulating film 50 will now be described in detail with reference to FIGS. 4 and 5.

The insulating film 50 includes the first insulating film 51 covering the electron supply layer 26 and the gate structure G, the second insulating film 52 covering the first insulating film 51, and the third insulating film 53 covering the second insulating film 52. A first field plate electrode 61 (described later) is embedded between the first insulating film 51 and the second insulating film 52 of the insulating film 50. A second field plate electrode 62 is embedded between the second insulating film 52 and the third insulating film 53 of the insulating film 50.

The first insulating film 51 is formed on the gate structure G and the electron supply layer 26. More specifically, the first insulating film 51 is formed on the gate electrode 40, a region of the gate layer 30 located closer to the drain electrode 44 than the gate electrode 40 is, and a region of the gate layer 30 located closer to the source electrode 42 than the gate electrode 40 is. Further, the first insulating film 51 is formed on a region of the electron supply layer 26 located between the gate layer 30 and the drain electrode 44, and a region of the electron supply layer 26 located between the gate layer 30 and the source electrode 42. In other words, the first insulating film 51 is in contact with and covers the upper surfaces of the gate electrode 40 and the above-described regions of the gate layer 30 and the electron supply layer 26.

The second insulating film 52 is formed on the first insulating film 51 and the first field plate electrode 61. In other words, an example of the second insulating film 52 is in contact with the upper surface of the first insulating film 51 and the upper surface of the first field plate electrode 61, and covers the upper surfaces of the first insulating film 51 and the first field plate electrode 61.

The third insulating film 53 is formed on the second insulating film 52 and the second field plate electrode 62. In other words, an example of the third insulating film 53 is in contact with the upper surface of the second insulating film 52 and the upper surface of the second field plate electrode 62, and covers the upper surfaces of the second insulating film 52 and the second field plate electrode 62.

The first insulating film 51 has a thickness, for example, between 30 nm and 80 nm, inclusive. The thickness of the first insulating film 51 is, for example, 50 nm. The second insulating film 52 has a thickness, for example, between 30 nm and 200 nm, inclusive. The thickness of the second insulating film 52 is, for example, 100 nm. The third insulating film 53 has a thickness, for example, between 50 nm and 200 nm, inclusive. The thickness of the third insulating film 53 is, for example, 100 nm. The thicknesses of the first insulating film 51, the second insulating film 52, and the third insulating film 53 may each be the thickness of, for example, a portion located on the electron supply layer 26 or a portion located on the gate structure G. The portion located on the gate structure G is, for example, a portion located on the gate electrode 40.

The insulating film 50 has a thickness, for example, between 110 nm and 480 nm, inclusive. The thickness of the insulating film 50 is, for example, 250 nm. The thickness of the insulating film 50 is a total sum of the thickness of the first insulating film 51, the thickness of the second insulating film 52, and the thickness of the third insulating film 53.

The first insulating film 51, the second insulating film 52, and the third insulating film 53 may each be composed of one of, or any combination of, silicon dioxide (SiO₂), silicon nitride (SiN), silicon oxynitride (SiON), alumina (Al₂O₃), AlN, and aluminum oxynitride (AlON). The first insulating film 51, the second insulating film 52, and the third insulating film 53 may be composed of the same material, or partially or entirely composed of different materials. In an example, the first insulating film 51 and the second insulating film 52 are composed of different materials, and the third insulating film 53 and the second insulating film 52 are composed of the same material. For example, the first insulating film 51 is composed of SiN, and the second insulating film 52 and the third insulating film 53 are composed of SiO₂.

### Detailed Structures of First Field Plate Electrode and Second Field Plate Electrode

The structures of the first field plate electrode 61 and the second field plate electrode 62 will now be described in detail with reference to FIG. 5.

The first field plate electrode 61 and the second field plate electrode 62 mitigate concentration of the electric field in the vicinity of an end of the gate layer 30 when a drain voltage is applied to the drain electrode 44 in a zero-bias state in which no gate voltage is applied to the gate electrode 40.

The drain electrode 44 is spaced apart from the first field plate electrode 61. The first field plate electrode 61 includes a first end 61A in the X-axis direction, and a second end 61B opposite to the first end 61A. The first end 61A is an end of the first field plate electrode 61 located relatively close to the drain electrode 44. The second end 61B is an end of the first field plate electrode 61 located relatively close to the source electrode 42.

The first end 61A of the first field plate electrode 61 is located between the gate layer 30 and the drain electrode 44 in the X-axis direction. In an example, between the gate layer 30 and the drain electrode 44, the first end 61A is located at a position relatively close to the gate layer 30. In an example, the first end 61A of the first field plate electrode 61 is located closer to the drain electrode 44 than a distal end 34A of the drain-side extension 34 of the gate layer 30 is in the X-axis direction. In this case, the first field plate electrode 61 includes a portion 61C located closer to the drain electrode 44 than the drain-side extension 34 is. The first end 61A of the first field plate electrode 61 may be located directly above the distal end 34A of the drain-side extension 34. In this case, the first field plate electrode 61 does not include the portion 61C, which is located closer to the drain electrode 44 than the drain-side extension 34 is.

The second end 61B of the first field plate electrode 61 is located closer to the source electrode 42 than the first side wall G1, which is a side wall of the gate structure G located relatively close to the drain electrode 44, is in the X-axis direction. The first field plate electrode 61 covers an end of the gate layer 30 (distal end 34A of drain-side extension 34), which is located relatively close to the drain electrode 44, with the first insulating film 51 located in between. This mitigates concentration of the electric field at an end of the gate layer 30 located relatively close to the drain electrode 44.

In an example, the second end 61B of the first field plate electrode 61 is spaced apart from the source electrode 42. For example, the second end 61B is located on the gate electrode 40. Specifically, the second end 61B may be located at a central position of the gate electrode 40 in the X-axis direction, or at a position located closer to the drain electrode 44 than the central position of the gate electrode 40 is in the X-axis direction. In this case, the first field plate electrode 61 may overlap the upper surface 40A of the gate electrode 40 over a relatively small area, thereby reducing a parasitic capacitance C1 formed between the first field plate electrode 61 and the upper surface 40A of the gate electrode 40. The second end 61B may be located closer to the source electrode 42 than the gate electrode 40 is in the X-axis direction.

Alternatively, the second end 61B may be located closer to the drain electrode 44 than the gate electrode 40 is in the X-axis direction. In this case, the first field plate electrode 61 does not include a portion overlapping the upper surface 40A of the gate electrode 40. This may eliminate or significantly reduce the parasitic capacitance C1 between the first field plate electrode 61 and the upper surface 40A of the gate electrode 40.

The first field plate electrode 61 includes an upper-surface facing part 61D facing the gate electrode 40 in the Z-axis direction, and a side-surface facing part 61E facing the first side wall G1 of the gate structure G in the X-axis direction. In an example, the side-surface facing part 61E is greater in area than the upper-surface facing part 61D. The area of the side-surface facing part 61E may be less than or equal to the area of the upper-surface facing part 61D.

The second field plate electrode 62 is spaced apart from the drain electrode 44. The second field plate electrode 62 includes a first end 62A in the X-axis direction, and a second end 62B opposite to the first end 62A. The first end 62A is an end of the second field plate electrode 62 located relatively close to the drain electrode 44. The second end 62B is an end of the second field plate electrode 62 located relatively close to the source electrode 42.

The first end 62A of the second field plate electrode 62 is located between the first end 61A of the first field plate electrode 61 and the drain electrode 44 in the X-axis direction. In an example, between the first end 61A and the drain electrode 44, the first end 62A is located at a position located relatively close to the first end 61A. In another example, between the first end 61A and the drain electrode 44, the first end 62A is located at a position located relatively close to the drain electrode 44.

The second end 62B of the second field plate electrode 62 is located closer to the drain electrode 44 than the first end 61A of the first field plate electrode 61 is in the X-axis direction. Also, the second end 62B is located closer to the drain electrode 44 than a second insulator 82 (described later) is in the X-axis direction. Therefore, the second field plate electrode 62 is selectively formed at a position located closer to the drain electrode 44 than the second insulator 82 (described later) is in the X-axis direction.

Alternatively, the second end 62B may be located closer to the drain electrode 44 than the gate electrode 40 is in the X-axis direction. In this case, the second field plate electrode 62 does not include a portion overlapping the upper surface 40A of the gate electrode 40. In an example, the second end 61B of the first field plate electrode 61 and the second end 62B of the second field plate electrode 62 are both located closer to the drain electrode 44 than the gate electrode 40 is in the X-axis direction.

The second field plate electrode 62 includes a portion located on the first field plate electrode 61, and a portion located closer to the drain electrode 44 than the first field plate electrode 61 is in the X-axis direction. The second field plate electrode 62 covers the first end 61A, which is an end of the first field plate electrode 61 located relatively close to the drain electrode 44, with the second insulating film 52 located in between.

In an example, the second end 62B of the second field plate electrode 62 is located between the second end 61B of the first field plate electrode 61 and the first side wall G1 of the gate structure G in the X-axis direction. In this case, the second end 62B may be located on the gate electrode 40. Alternatively, the second end 62B may be located closer to the source electrode 42 than the second end 61B of the first field plate electrode 61 is in the X-axis direction.

Although not shown in FIGS. 4 and 5, the first field plate electrode 61 and the second field plate electrode 62 are both electrically connected to the source electrode 42. The connection structure between the first field plate electrode 61 and the second field plate electrode 62 and the source electrode 42 will be described later in detail.

The first field plate electrode 61 has a thickness, for example, between 30 nm and 80 nm, inclusive. The thickness of the first field plate electrode 61 is, for example, 50 nm. The second field plate electrode 62 has a thickness, for example, between 30 nm and 130 nm, inclusive. The thickness of the second field plate electrode 62 is, for example, 80 nm. The thicknesses of the first field plate electrode 61 and the second field plate electrode 62 may each be the thickness of, for example, a portion located on the electron supply layer 26 or a portion located on the gate structure G. The portion located on the gate structure G is, for example, a portion located on the gate electrode 40.

The first field plate electrode 61 and the second field plate electrode 62 may each include one or more metal layers. In an example, the first field plate electrode 61 and the second field plate electrode 62 may each be composed of one of, or any combination of, Ti, TiN, Al, aluminum silicon copper (AlSiCu), and aluminum copper (AlCu). The first field plate electrode 61 and the second field plate electrode 62 may be composed of the same material or different materials. In an example, the first field plate electrode 61 and the second field plate electrode 62 are both composed of TiN.

### First Insulator and Second Insulator

As shown in FIGS. 4 and 5, the nitride semiconductor device 10 includes sidewall structures respectively extending along the first side wall G1 and the second side wall G2 of the gate structure G with the first insulating film 51 located in between. These side-wall structures include a first insulator 81 and the second insulator 82.

The first insulator 81 is formed between the first insulating film 51 and the first field plate electrode 61. The first insulator 81 faces the first side wall G1 of the gate structure G with the first insulating film 51 located in between in the X-axis direction. In plan view, the first insulator 81 is disposed within a range R1 in which the gate layer 30 is formed.

In an example, the first insulator 81 includes an end 81A located relatively close to the drain electrode 44. The end 81A is located farther from the drain electrode 44 than the first end 61A of the first field plate electrode 61, which is located relatively close to the drain electrode 44, is in the X-axis direction. In other words, the first field plate electrode 61 has a distal end located closer to the drain electrode 44 than the first insulator 81 is in the X-axis direction. Furthermore, the end 81A of the first insulator 81, which is located relatively close to the drain electrode 44, is located farther from the drain electrode 44 than the distal end 34A of the drain-side extension 34 is. In other words, the drain-side extension 34 has a distal end located closer to the drain electrode 44 than the first insulator 81 is in the X-axis direction. In this case, a certain range of the electron supply layer 26 extending from the distal end 34A of the drain-side extension 34 in the X-axis direction is not covered by the first insulator 81 and is covered by the first field plate electrode 61 without the first insulating film 51 located in between.

The first insulator 81 includes an upper surface 81B sloped toward the electron supply layer 26 as the upper surface 81B extends from the gate structure G toward the drain electrode 44. For example, the upper surface 81B of the first insulator 81 is more inclined relative to the first side wall G1 than a surface (upper surface) 51A of a portion of the first insulating film 51 covering the first side wall G1 of the gate structure G.

In an example, the shape of the upper surface 81B continuously changes over its entire length in the X-axis direction, such that the dimension of the first insulator 81 in the Z-axis direction decreases as the first insulator 81 extends from the gate structure G toward the drain electrode 44. For example, the upper surface 81B is an entirely curved surface projecting in a direction extending from the gate structure G toward the drain electrode 44.

The gradient of the slope of the upper surface 81B does not have to be constant. For example, the upper surface 81B may be a sloped surface formed by curved surfaces having different curvatures, a sloped surface formed by flat inclined surfaces having different inclination angles, or a sloped surface formed by both curved surfaces having different curvatures and flat inclined surfaces having different inclination angles. Furthermore, the upper surface 81B may partially include a surface parallel to the upper surface 26A of the electron supply layer 26.

In an example, the upper surface 81B includes an end 81C located relatively close to the first side wall G1. The end 81C is located upward from the gate electrode 40 in the Z-axis direction. An interface between the first insulating film 51 and the first field plate electrode 61 is partially located on the gate electrode 40, and the end 81C is located downward from this part of the interface in the Z-axis direction.

The first insulator 81 has a thickness, for example, between 200 nm and 300 nm, inclusive. The thickness of the first insulator 81 may be defined by, for example, a distance between the end 81A and the end 81C in the Z-axis direction.

The second insulator 82 is formed between the first insulating film 51 and the second insulating film 52. The second insulator 82 faces the second side wall G2 of the gate structure G with the first insulating film 51 located in between in the X-axis direction. In plan view, the second insulator 82 is disposed within the range R1 in which the gate layer 30 is formed.

In an example, the second insulator 82 includes an end 82A located relatively close to the source electrode 42. The end 82A is located farther from the source electrode 42 than the distal end 33A of the source-side extension 33 is. In other words, the source-side extension 33 has a distal end located closer to the source electrode 42 than the second insulator 82 is in the X-axis direction. In an example, the source extension 42B of the source electrode 42 is partially located on the second insulator 82.

The second insulator 82 includes an upper surface 82B sloped toward the electron supply layer 26 as the upper surface 82B extends from the gate structure G toward the source electrode 42. For example, the upper surface 82B of the second insulator 82 is more inclined relative to the second side wall G2 than a surface (upper surface) 51B of a portion of the first insulating film 51 covering the second side wall G2 of the gate structure G.

In an example, the shape of the upper surface 82B continuously changes over its entire length in the X-axis direction, such that the dimension of the second insulator 82 in the Z-axis direction decreases as the second insulator 82 extends from the gate structure G toward the source electrode 42. For example, the upper surface 82B is an entirely curved surface projecting in a direction extending from the gate structure G toward the source electrode 42.

The gradient of the slope of the upper surface 82B does not have to be constant. For example, the upper surface 82B may be a sloped surface formed by curved surfaces having different curvatures, a sloped surface formed by flat inclined surfaces having different inclination angles, or a sloped surface formed by both curved surfaces having different curvatures and flat inclined surfaces having different inclination angles. Furthermore, the upper surface 82B may partially include a surface parallel to the upper surface 26A of the electron supply layer 26.

In an example, the upper surface 82B includes an end 82C located relatively close to the second side wall G2. The end 82C is located upward from the gate electrode 40 in the Z-axis direction. An interface between the first insulating film 51 and the second insulating film 52 is partially located on the gate electrode 40, and the end 82C is located downward from this part of the interface in the Z-axis direction.

The second insulator 82 has a thickness, for example, between 100 nm and 300 nm, inclusive. The thickness of the second insulator 82 may be defined by, for example, a distance between the end 82A and the end 82C in the Z-axis direction.

The upper surface 82B of the second insulator 82 and the upper surface 81B of the first insulator 81 may be symmetric (plane-symmetric). The upper surface 82B of the second insulator 82 and the upper surface 81B of the first insulator 81 do not have to be symmetric. That is, the upper surface 82B of the second insulator 82 and the upper surface 81B of the first insulator 81 may be sloped differently.

The first insulator 81 and the second insulator 82 may each be composed of one of, or any combination of, silicon dioxide (SiO₂), silicon nitride (SiN), silicon oxynitride (SiON), alumina (Al₂O₃), AlN, and aluminum oxynitride (AlON). The first insulator 81 and the second insulator 82 may be composed of the same material or different materials. In an example, the first insulator 81 and the second insulator 82 are composed of the same material. The first insulator 81 and the second insulator 82 are composed of, for example, SiO₂. The material of the first insulator 81 and the second insulator 82 may be the same as, or differ from, that of the first insulating film 51. In an example, the material of the first insulator 81 and the second insulator 82 differs from the material of the first insulating film 51.

### Exemplary Planar Layout of Nitride Semiconductor Device

An exemplary planar layout of the HEMT structure (nitride semiconductor device 10) will now be described with reference to FIGS. 2 and 3. For clarity of illustration, the insulating film 50 is transparent in FIG. 2. In FIG. 2, the first field plate electrode 61 is indicated by broken lines, and the second field plate electrode 62 is indicated by double-dashed lines.

The nitride semiconductor device 10 includes multiple transistor elements, each having a HEMT structure, in an active region. In the example shown in FIG. 2, the transistor elements are arranged next to each other in both the X-axis direction and the Y-axis direction.

The source electrodes 42 and the drain electrodes 44 extend in the Y-axis direction in plan view. The source electrodes 42 and the drain electrodes 44 are alternately arranged at intervals in the X-axis direction in plan view. Alternatively, the nitride semiconductor device 10 may include the source electrodes 42 arranged at intervals in the Y-axis direction, and the drain electrodes 44 arranged at intervals in the Y-axis direction.

The gate structure G includes a main body portion G3, an intermediate joining portion G4, and an end joining portion G5. The main body portion G3, the intermediate joining portion G4, and the end joining portion G5 each include the gate layer 30, and the gate electrode 40 formed on the gate layer 30.

In plan view, multiple main body portions G3 extend in the Y-axis direction and are arranged at intervals in the X-axis direction. Two adjacent main body portions G3 in the X-axis direction are located at opposite sides of the source electrode 42 or the drain electrode 44. Therefore, the source electrodes 42 and the drain electrodes 44 are alternately arranged in the X-axis direction with the main body portion G3 of the gate structure G located in between.

The intermediate joining portion G4 joins two main body portions G3 that are adjacent to each other in the X-axis direction with the source electrode 42 located in between. The intermediate joining portion G4 is located between two source electrodes 42 that are adjacent to each other in the Y-axis direction, and joins the main body portions G3 at an intermediate position between the two adjacent source electrodes 42 in the Y-axis direction. The end joining portion G5 joins two main body portions G3 that are adjacent to each other in the X-axis direction with the drain electrode 44 located in between. The end joining portion G5 joins the main body portions G3 at an end position of the gate structure G in the Y-axis direction.

The first field plate electrode 61 includes a first body portion 61F and a first joining portion 61G.

In plan view, multiple first body portions 61F extend in the Y-axis direction and are arranged at intervals in the X-axis direction. Two adjacent first body portions 61F in the X-axis direction are located at opposite sides of the source electrode 42 or the drain electrode 44. In plan view, the first body portion 61F partially overlaps the main body portion G3 of the gate structure G. An edge of the first body portion 61F located relatively close to the drain electrode 44 is the first end 61A of the first field plate electrode 61, and an edge of the first body portion 61F located relatively close to the source electrode 42 is the second end 61B of the first field plate electrode 61.

The first joining portion 61G joins two first body portions 61F that are adjacent to each other with the source electrode 42 located in between in the X-axis direction. In plan view, the first joining portion 61G and the source electrode 42 are located at different positions. In other words, the first joining portion 61G does not overlap the source electrode 42.

The second field plate electrode 62 includes a second body portion 62C and a second joining portion 62D.

In plan view, multiple second body portions 62C extend in the Y-axis direction and are arranged at intervals in the X-axis direction. Two adjacent second body portions 62C in the X-axis direction are located at opposite sides of the source electrode 42 or the drain electrode 44. In plan view, the second body portion 62C partially overlaps the first body portion 61F of the first field plate electrode 61. An edge of the second body portion 62C located relatively close to the drain electrode 44 is the first end 62A of the second field plate electrode 62, and an edge of the second body portion 62C located relatively close to the source electrode 42 is the second end 62B of the second field plate electrode 62.

The second joining portion 62D joins two second body portions 62C that are adjacent to each other with the source electrode 42 located in between in the X-axis direction. In plan view, the second joining portion 62D, the source electrode 42, and the first joining portion 61G of the first field plate electrode 61 are located at different positions. In other words, the second joining portion 62D does not overlap the source electrode 42 or the first joining portion 61G.

As shown in FIG. 3, the nitride semiconductor device 10 includes a gate interconnect 72, a source interconnect 74, and a drain interconnect 76. The gate interconnect 72, the source interconnect 74, and the drain interconnect 76 are arranged on an first interlayer insulating layer (not shown) that covers the source electrodes 42, the drain electrodes 44, and the insulating film 50. In FIG. 3, the gate interconnect 72, the source interconnect 74, and the drain interconnect 76 are placed upon on the plan view diagram shown in FIG. 2. For clarity of illustration, the gate layer 30 is not shown in FIG. 3.

In the example shown in FIG. 3, the gate interconnect 72, the source interconnect 74, and the drain interconnect 76 each extend in the X-axis direction. The gate interconnect 72, the source interconnect 74, and the drain interconnect 76 are spaced apart from each other in the Y-axis direction. The gate interconnect 72 extends in a range that overlaps the gate electrode 40 located in the intermediate joining portion G4 or the end joining portion G5 of the gate structure G in plan view. The source interconnect 74 extends in a range that overlaps the source electrode 42, the first joining portion 61G of the first field plate electrode 61, and the second joining portion 62D of the second field plate electrode 62 in plan view. The drain interconnect 76 extends in a region that overlaps the drain electrode 44 in plan view.

In an example, the gate interconnect 72 is connected to the gate electrode 40 by a gate-connected conductor 73. The gate-connected conductor 73 extends through the first interlayer insulating layer to the gate electrode 40. The source interconnect 74 is connected to the source electrode 42 by a first source-connected conductor 75A. The first source-connected conductor 75A extends through the first interlayer insulating layer. The source interconnect 74 is connected to the first joining portion 61G of the first field plate electrode 61 by a second source-connected conductor 75B. The second source-connected conductor 75B extends through the first interlayer insulating layer. The source interconnect 74 is connected to the second joining portion 62D of the second field plate electrode 62 by a third source-connected conductor 75C. The third source-connected conductor 75C extends through the first interlayer insulating layer. The drain interconnect 76 is connected to the drain electrode 44 by a drain-connected conductor 77. The drain-connected conductor 77 extends through the first interlayer insulating layer.

The gate-connected conductor 73, the first source-connected conductor 75A, the second source-connected conductor 75B, the third source-connected conductor 75C, and the drain-connected conductor 77 are, for example, vias extending through the first interlayer insulating layer. Any number of gate-connected conductors 73, first source-connected conductors 75A, second source-connected conductors 75B, third source-connected conductors 75C, and drain-connected conductors 77 may be arranged.

The gate interconnect 72, the source interconnect 74, and the drain interconnect 76 are covered by, for example, a second interlayer insulating layer (not shown). In an example, the gate pad 14, the source pads 16, and the drain pads 18, which are shown in FIG. 1, are arranged on the second interlayer insulating layer.

In an example, the gate interconnect 72 is connected to the gate pad 14 by a gate-connected conductor (not shown). The gate-connected conductor extends through the second interlayer insulating layer to the gate pad 14. The source interconnect 74 is connected to the source pad 16 by a source-connected conductor (not shown). The source-connected conductor extends through the second interlayer insulating layer. The drain interconnect 76 is connected to the drain pad 18 by a drain-connected conductor (not shown). The drain-connected conductor extends through the second interlayer insulating layer.

### Method for Manufacturing the Nitride Semiconductor Device

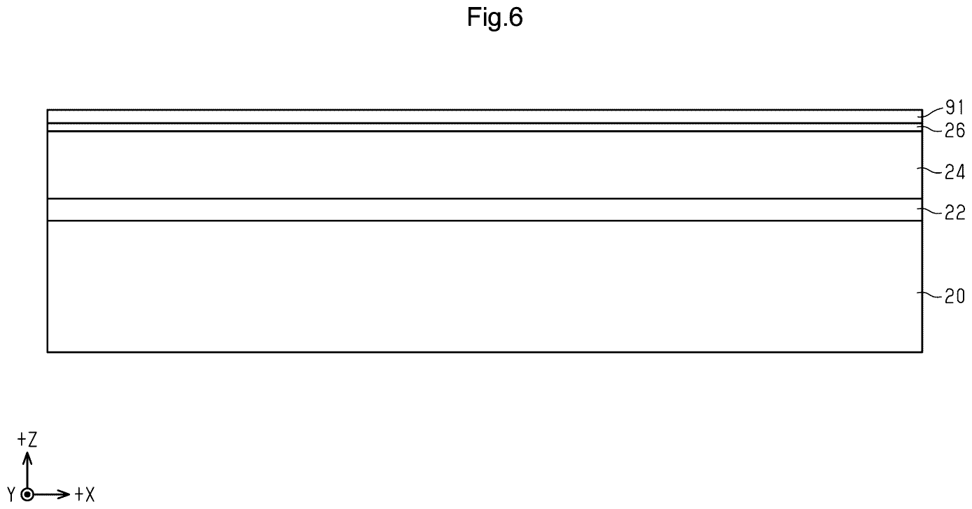

A method for manufacturing the nitride semiconductor device 10 will now be described with reference to FIGS. 6 to 23. FIGS. 6 to 23 are schematic cross-sectional views illustrating exemplary manufacturing steps of the nitride semiconductor device 10. To facilitate understanding, same reference characters are given to those elements that are the same as the corresponding elements of the nitride semiconductor device 10 shown in FIG. 1.

As shown in FIG. 6, the method for manufacturing the nitride semiconductor device 10 includes sequentially forming the buffer layer 22, the electron transit layer 24, the electron supply layer 26, and a nitride semiconductor layer 91 on the substrate 20, which is, for example, a Si substrate. The buffer layer 22, the electron transit layer 24, the electron supply layer 26, and the nitride semiconductor layer 91 may be epitaxially grown by a metal organic chemical vapor deposition (MOCVD).

In an example, the buffer layer 22 may be a multilayer buffer layer. The multilayer buffer layer may include an AlN layer (first buffer layer) formed on the substrate 20, and a graded AlGaN layer (second buffer layer) formed on the AlN layer. The graded AlGaN may be formed by, for example, stacking three AlGaN layers having Al compositions of 75%, 50%, and 25% in this order from the side closer to the AlN layer.

The electron transit layer 24 is, for example, a GaN layer. The electron supply layer 26 formed on the electron transit layer 24 is, for example, an AlGaN layer. Thus, the electron supply layer 26 is composed of a nitride semiconductor having a larger band gap than the electron transit layer 24. The nitride semiconductor layer 91 is a layer for forming the gate layer 30. The nitride semiconductor layer 91 is, for example, a p-type GaN layer.

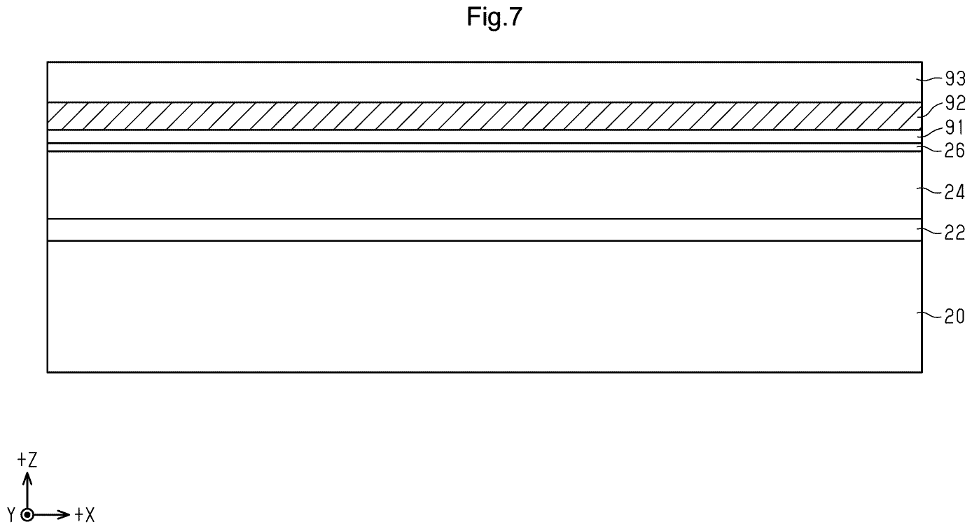

In the following manufacturing step illustrated in FIG. 7, an electrode layer 92 and a protection layer 93 are sequentially formed on the nitride semiconductor layer 91. The electrode layer 92 is a layer for forming the gate electrode 40 and is formed by, for example, sputtering. In an example, the electrode layer 92 is a TiN layer. In an example, the protection layer 93 is a SiN layer. The protection layer 93 is formed by, for example, plasma-chemical vapor deposition (PECVD).

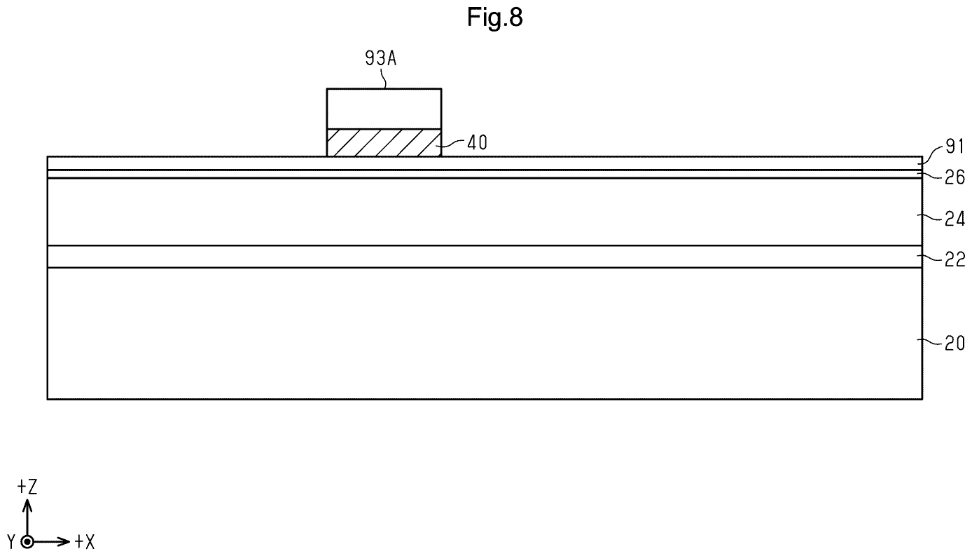

In the following manufacturing step illustrated in FIG. 8, the electrode layer 92 and the protection layer 93 are selectively removed by lithography and etching. As a result, the residual portion of the electrode layer 92 becomes the gate electrode 40. Further, the residual portion of the protection layer 93 becomes a protection portion 93A.

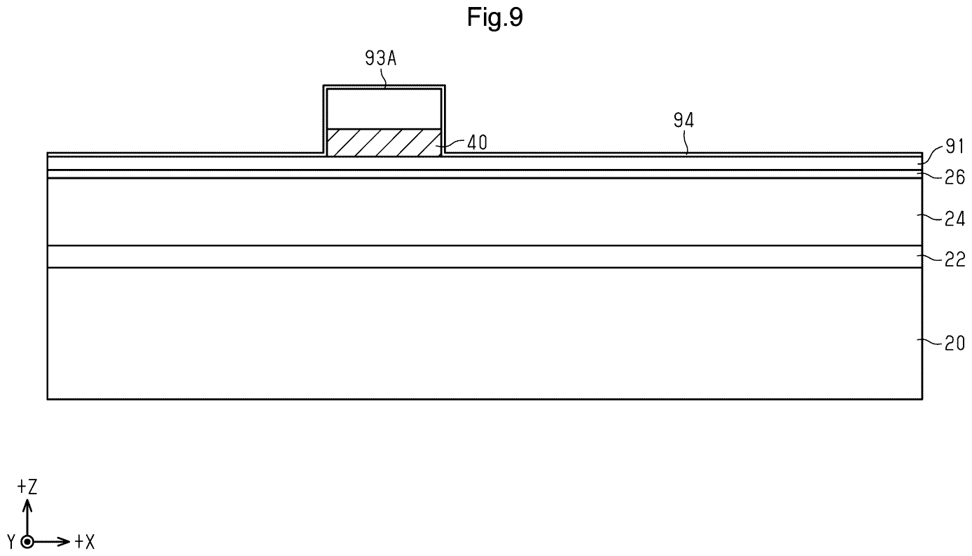

In the following manufacturing step illustrated in FIG. 9, a protection layer 94 is formed to cover the gate electrode 40, the protection portion 93A, and the nitride semiconductor layer 91. The protection layer 94 may be a SiN layer formed by, for example, PECVD.

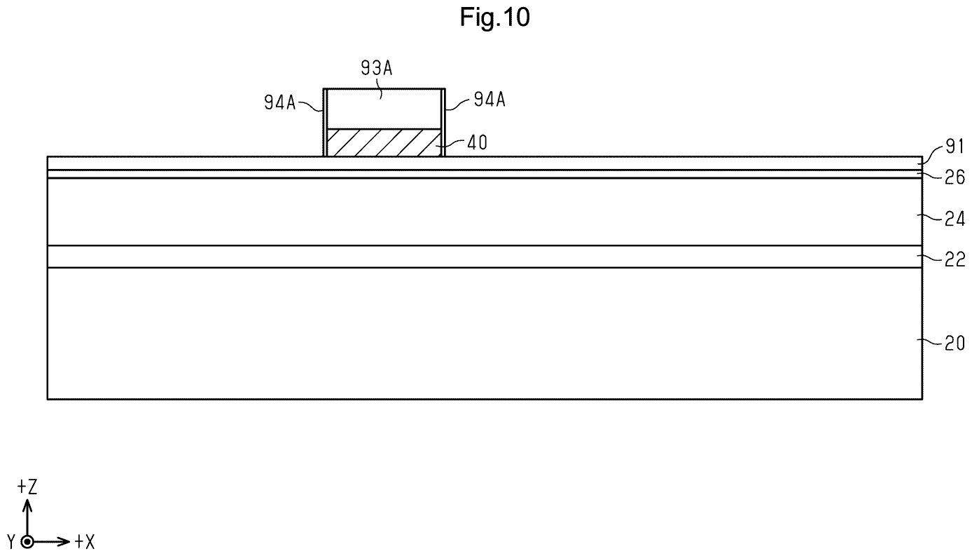

In the following manufacturing step illustrated in FIG. 10, the protection layer 94 is etched back until the upper surface of the nitride semiconductor layer 91 is exposed. As a result of the etching back, the residual portion of the protection layer 94 becomes protection walls 94A that cover the side walls of the gate electrode 40 and the protection portion 93A.

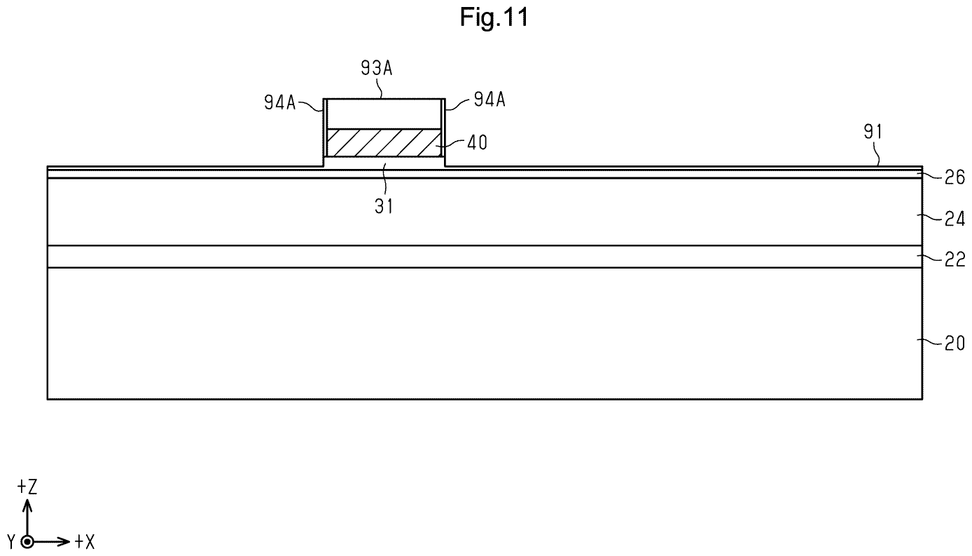

In the following manufacturing step illustrated in FIG. 11, the nitride semiconductor layer 91 is etched (e.g., dry etched) to a given depth using the protection portion 93A and the protection walls 94A as masks, so as to form the ridge 31 of the gate layer 30. In this step, a thin portion of the nitride semiconductor layer 91 remains at opposite sides of the ridge 31. These thin portions have a thickness that corresponds to the source-side extension 33 and the drain-side extension 34. Subsequently, the protection portion 93A and the protection wall 94A are removed.

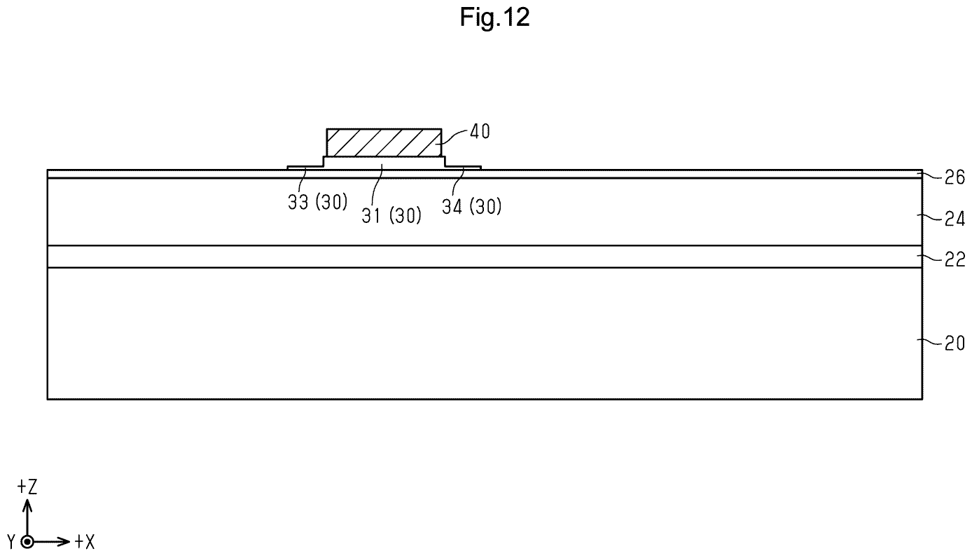

In the following manufacturing step illustrated in FIG. 12, the thin portion of the nitride semiconductor layer 91 (refer to FIG. 11) is selectively etched using a mask (not shown) that covers the gate electrode 40 and the ridge 31, so as to form the source-side extension 33 and the drain-side extension 34. Then, the mask (not shown) is removed. In this manner, the gate layer 30, including the ridge 31, the source-side extension 33, and the drain-side extension 34, is formed.

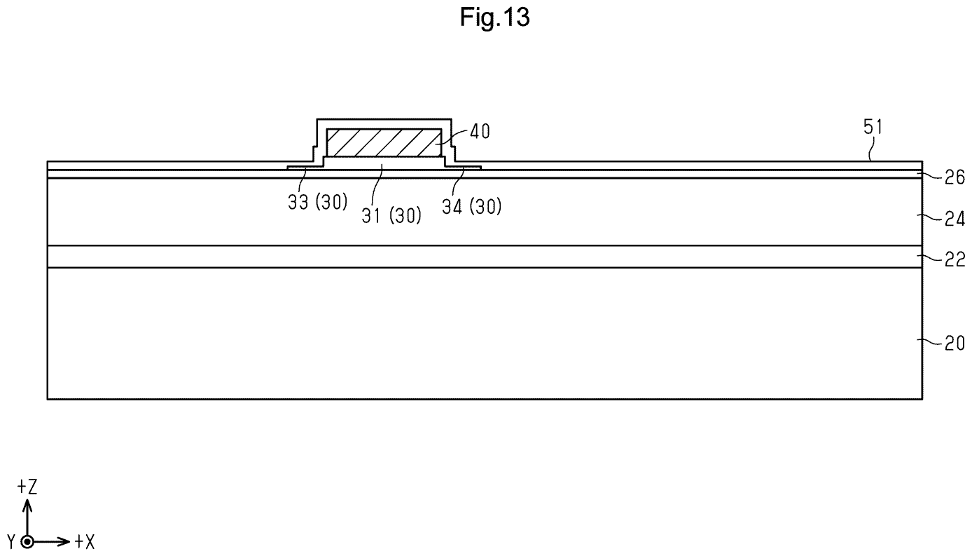

In the following manufacturing step illustrated in FIG. 13, the first insulating film 51 is formed to cover the electron supply layer 26, the gate layer 30, and the gate electrode 40. In an example, the first insulating film 51 is a SiN layer. The first insulating film 51 is formed by, for example, low-pressure chemical vapor deposition (LPCVD).

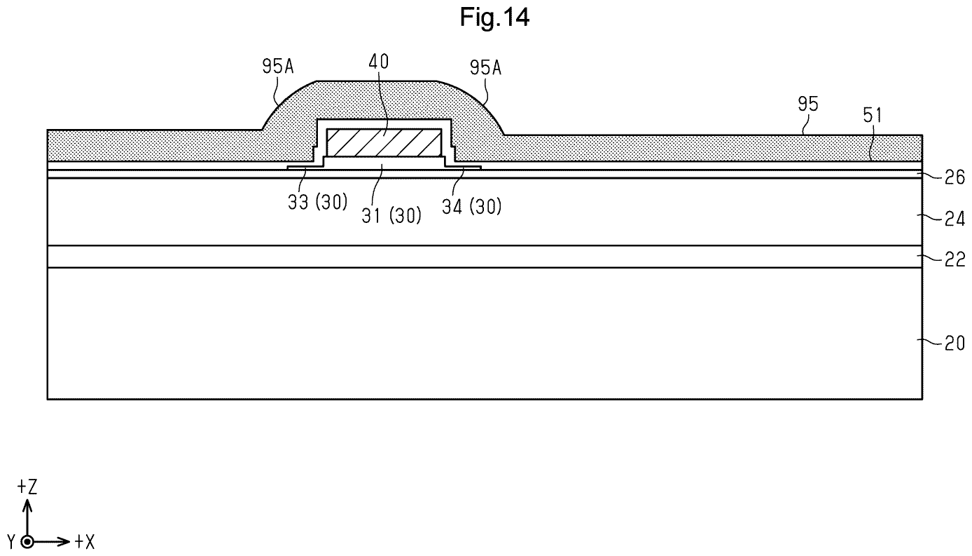

In the following manufacturing step illustrated in FIG. 14, an insulator layer 95 is formed to cover the first insulating film 51. The insulator layer 95 is a layer for forming the first insulator 81 and the second insulator 82. In an example, the insulator layer 95 is a SiO₂ layer. The insulator layer 95 is formed by, for example, plasma chemical vapor deposition (PCVD).

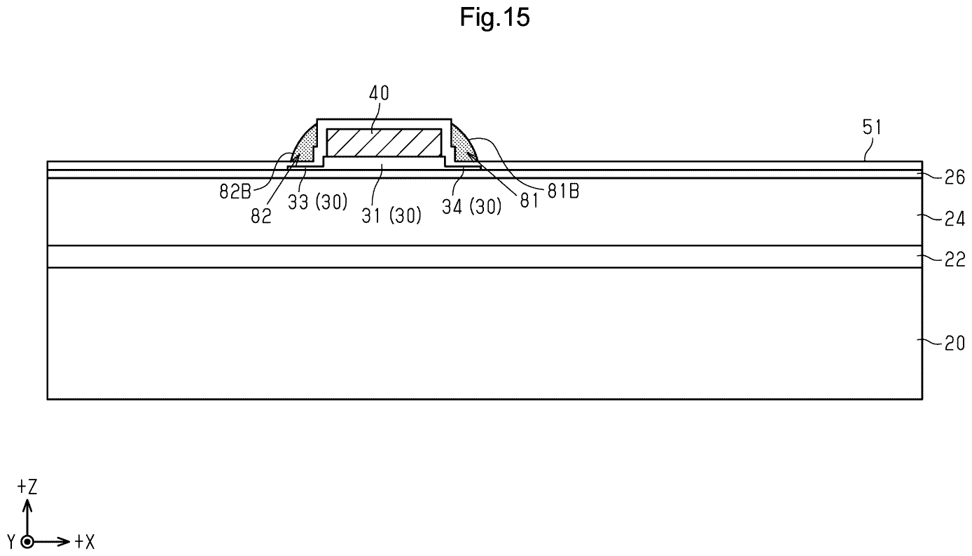

In the following manufacturing step illustrated in FIG. 15, the insulator layer 95 is etched back until the upper surface of the first insulating film 51 is exposed. As a result of the etching back, the residual portion of the insulator layer 95 becomes the first insulator 81 and the second insulator 82.

Preferably, a relatively thick insulator layer 95 is formed in the manufacturing step illustrated in FIG. 14. For example, the insulator layer 95 has a thickness between 150 nm and 350 nm, inclusive. When the insulator layer 95 is relatively thick, a sloped surface 95A may be formed in a portion located above the source-side extension 33 and a portion located above the drain-side extension 34. The sloped surface 95A is sloped toward the nitride semiconductor layer 91 as the sloped surface 95A extends away from the gate electrode 40. After the etching back of the manufacturing step illustrated in FIG. 15, these sloped surfaces 95A become the upper surface 81B of the first insulator 81 and the upper surface 82B of the second insulator 82.

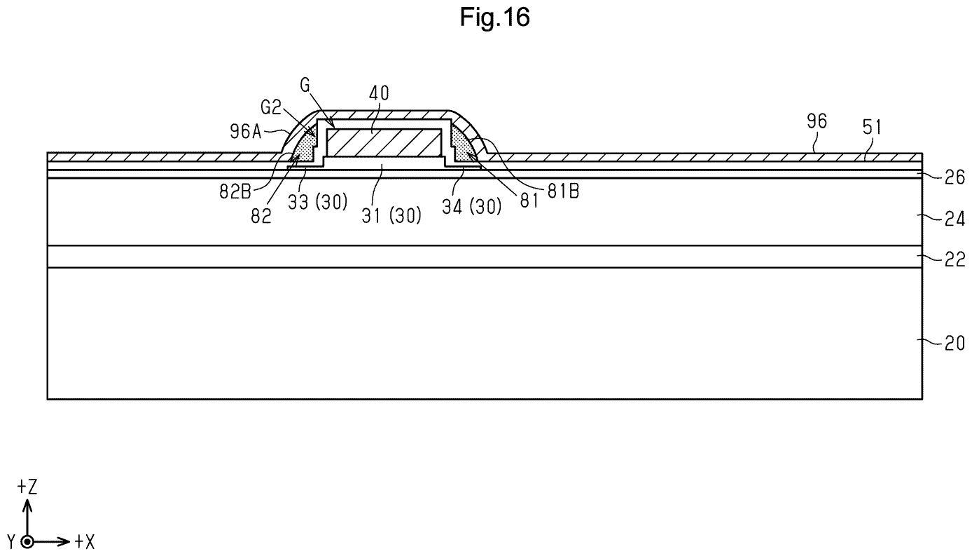

In the following manufacturing step illustrated in FIG. 16, an electrode layer 96 is formed to cover the first insulator 81, the second insulator 82, and the first insulating film 51. The electrode layer 96 is a layer for forming the first field plate electrode 61 and is formed by, for example, sputtering. In an example, the electrode layer 96 is a TiN layer.

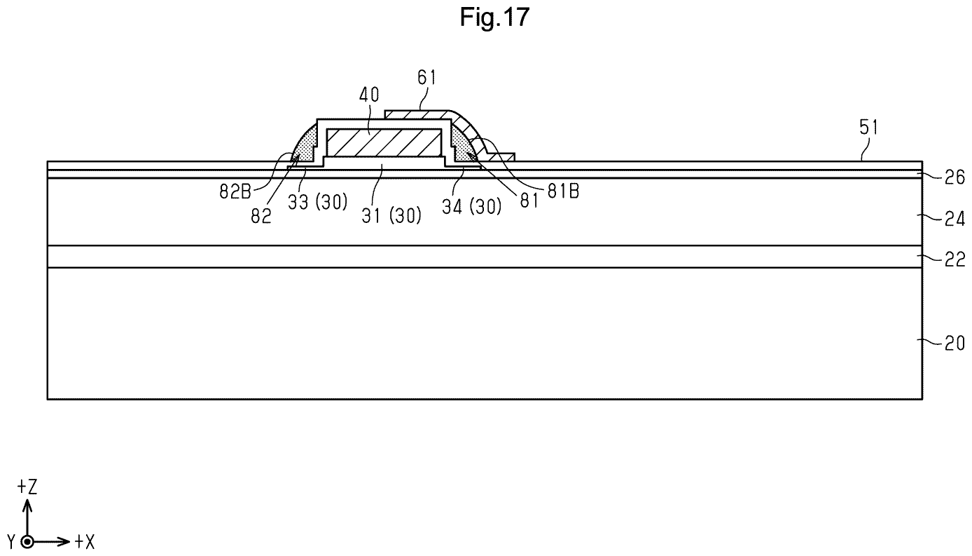

In the following manufacturing step illustrated in FIG. 17, the electrode layer 96 is selectively removed by etching. As a result, the residual portion of the electrode layer 96 becomes the first field plate electrode 61.

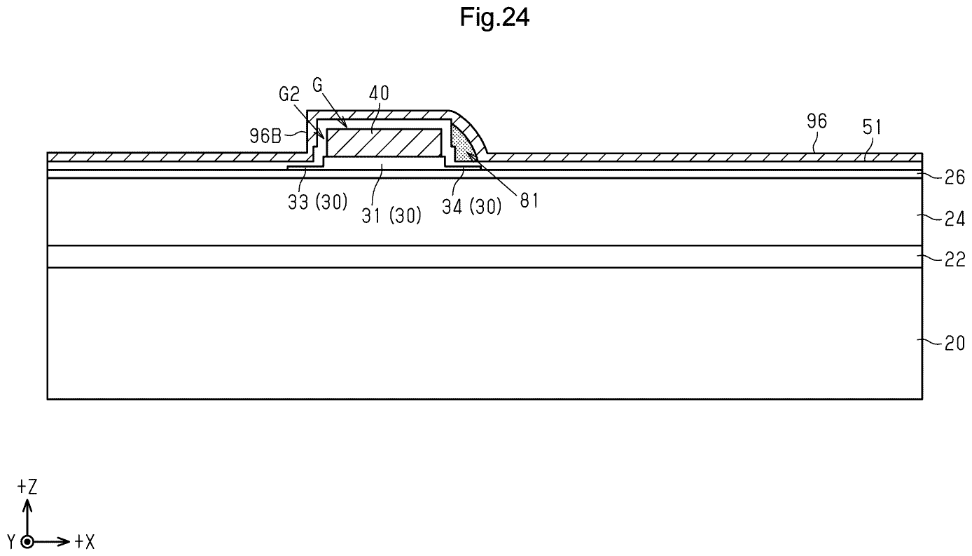

In a comparative example in which the second insulator 82 is not formed, after the electrode layer 96 is selectively removed by etching, unwanted residue may remain. More specifically, as shown in FIG. 24, when the electrode layer 96 is formed without the second insulator 82, the electrode layer 96 may include an upright part 96B that extends in the Z-axis direction along the second side wall G2 of the gate structure G with the first insulating film 51 located in between. In this case, the upright part 96B has a thickness in the X-axis direction. Therefore, when etching the electrode layer 96 in the Z-axis direction, the upright part 96B cannot be etched in its thickness-wise direction. Accordingly, the upright part 96B may not be completely removed.

In contrast, in the present embodiment, the electrode layer 96 is formed after the second insulator 82 is formed (refer to FIG. 16). In this case, the electrode layer 96 includes a sloped part 96A that extends along the second side wall G2 of the gate structure G with the first insulating film 51 located in between. The sloped part 96A is sloped in correspondence with the upper surface 82B of the second insulator 82. This sloped part 96A has a thickness in a direction that is closer to the Z-axis direction than the upright part 96B. Therefore, when etching the electrode layer 96 in the Z-axis direction, the electrode layer 96 may be removed at an angle relatively close to the thickness-wise direction of the sloped part 96A. Accordingly, the sloped part 96A of the electrode layer 96 may be removed by the etching of FIG. 17 without leaving unwanted residue.

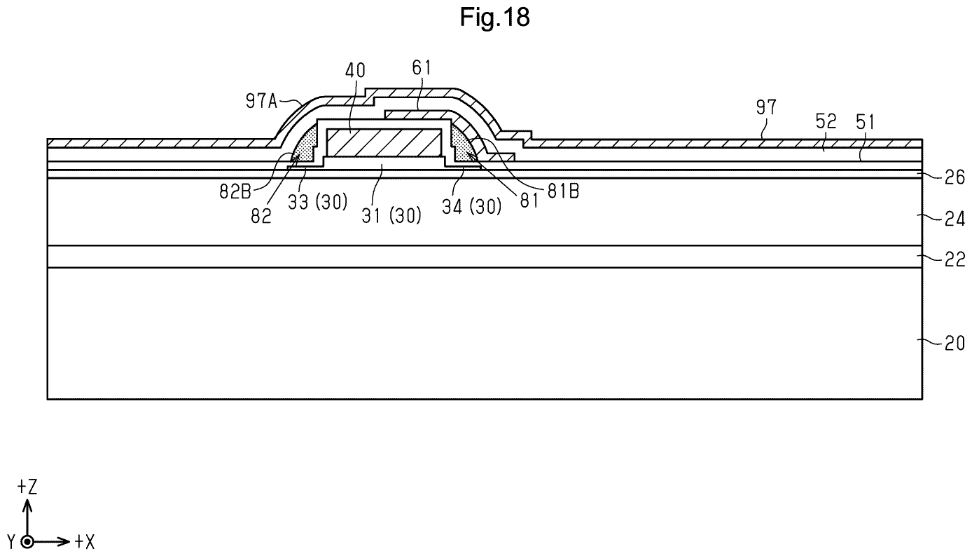

In the following manufacturing step illustrated in FIG. 18, the second insulating film 52 and an electrode layer 97 are sequentially formed to cover the second insulator 82, the first field plate electrode 61, and the first insulating film 51. In an example, the second insulating film 52 is a SiO₂ layer. The second insulating film 52 is formed by, for example, PCVD. The electrode layer 97 is a layer for forming the second field plate electrode 62 and is formed by, for example, sputtering. In an example, the electrode layer 97 is a TiN layer.

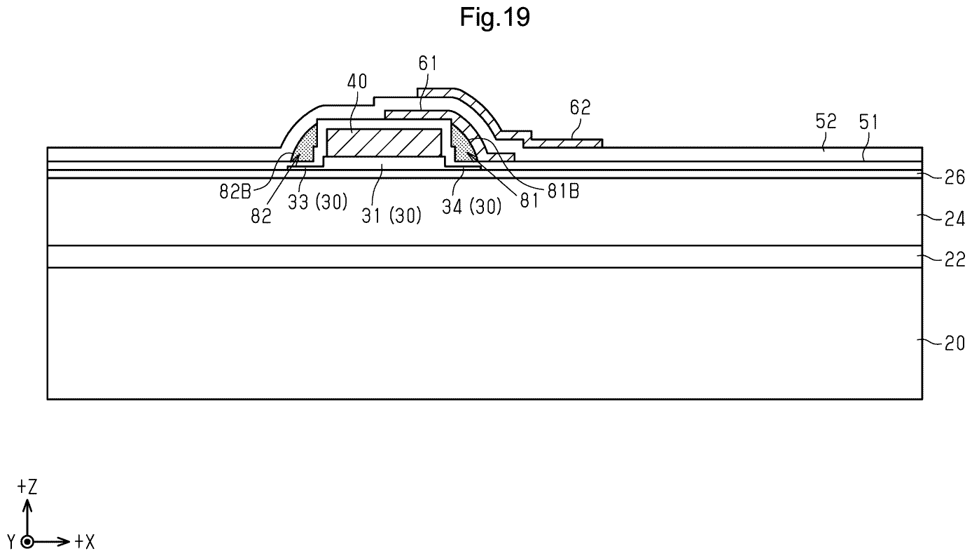

In the following manufacturing step illustrated in FIG. 19, the electrode layer 97 is selectively removed by etching. As a result, the residual portion of the electrode layer 97 becomes the second field plate electrode 62. In the step of etching the electrode layer 97, the same advantage as the step of etching the electrode layer 96 may be obtained by the second insulator 82 having the upper surface 82B. More specifically, since the second insulator 82 having the upper surface 82B is formed, the electrode layer 97 includes a sloped part 97A (shown in FIG. 18) that extends along the second side wall G2 of the gate structure G, in the same manner as the sloped part 96A of the electrode layer 96 (refer to FIG. 16). Accordingly, the sloped part 97A of the electrode layer 97 may be removed by the etching of FIG. 19 without leaving unwanted residue.

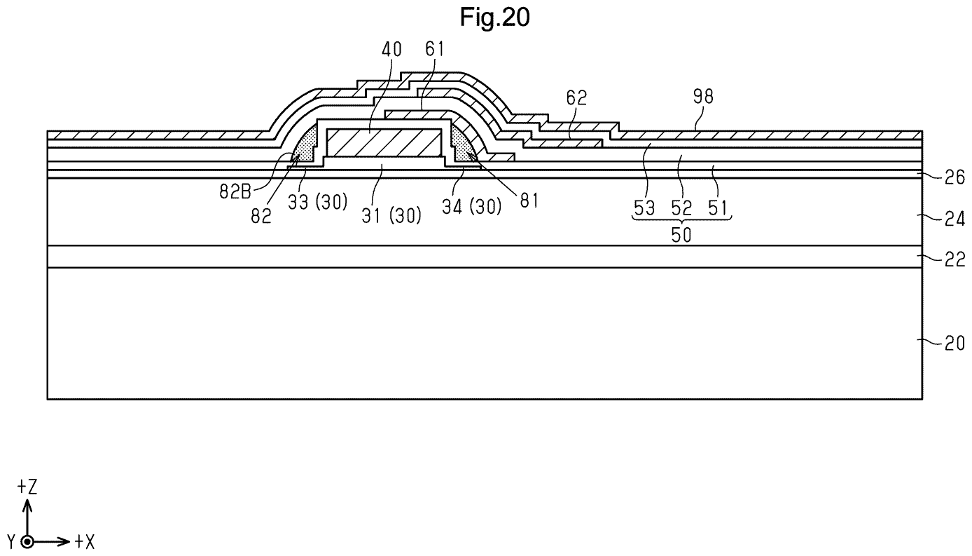

In the following manufacturing step illustrated in FIG. 20, the third insulating film 53 and an electrode layer 98 are sequentially formed to cover the second field plate electrode 62 and the second insulating film 52. In an example, the third insulating film 53 is a SiO₂ layer. The third insulating film 53 is formed by, for example, PCVD. The electrode layer 98 is a layer forming the barrier metal layer 42C and is formed by, for example, sputtering. In an example, the electrode layer 98 is a TiN layer.

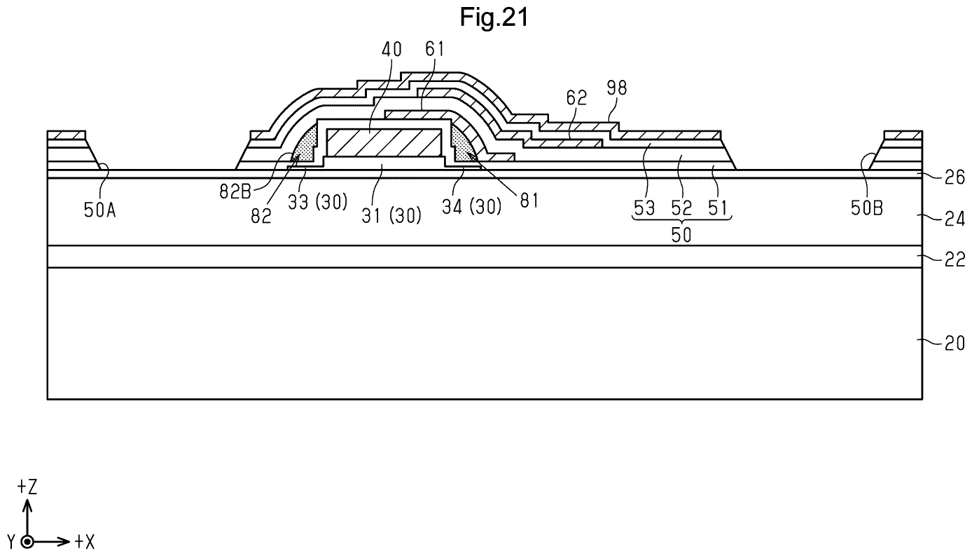

In the following manufacturing step illustrated in FIG. 21, the source opening 50A and the drain opening 50B are formed by selectively etching the electrode layer 98, the third insulating film 53, the second insulating film 52, and the first insulating film 51, using a mask (not shown) formed on the electrode layer 98. As a result, the insulating film 50 includes the source opening 50A and the drain opening 50B.

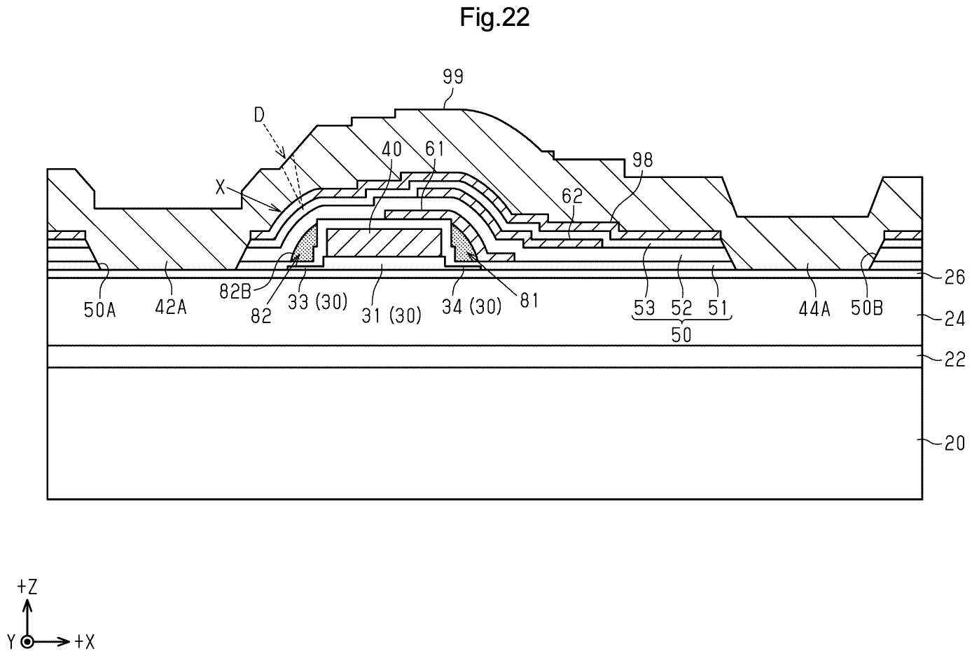

In the following manufacturing step illustrated in FIG. 22, an electrode layer 99 is formed to cover the electrode layer 98 and fill the source opening 50A and the drain opening 50B. The electrode layer 99 is a layer for forming the source electrode 42 and the drain electrode 44, and is formed by, for example, sputtering. When the electrode layer 98 is formed, the source opening 50A is filled with the source contact 42A, and the drain opening 50B is filled with the drain contact 44A. In an example, the electrode layer 99 has a four-layer structure (Ti layer/AlCu layer/Ti layer/TiN layer).

Since the second insulator 82 having the upper surface 82B is formed, the second insulating film 52, the third insulating film 53, and the electrode layer 98 each have a specific portion X (shown in FIG. 22) located on the second insulator 82. The specific portion X is sloped in correspondence with the upper surface 82B of the second insulator 82. As a result, wire breakage of the electrode layer 99 formed on the second insulating film 52, the third insulating film 53, and the electrode layer 98 is avoided.

More specifically, in a comparative example in which the second insulator 82 having the upper surface 82B is not formed, the specific portions X of the second insulating film 52, the third insulating film 53, and the electrode layer 98 may form steps in correspondence with the second side wall G2 of the gate structure G. Since the steps of the specific portions X are orthogonal to, or substantially orthogonal to, an XY-plane, when the electrode layer 99 is formed on the specific portions X of the second insulating film 52, the third insulating film 53, and the electrode layer 98, a groove-like recess (indicated by broken line D) may be formed in a portion of the electrode layer 99 located above the steps formed by the specific portions X. In other words, the electrode layer 99 may be partially thin in a portion located above the steps of the specific portions X. This recess of the partially-thin portion may become a cause of wire breakage of the source extension 42B of the source electrode 42, which is formed by the electrode layer 99.

In contrast, in a case in which the second insulator 82 having the upper surface 82B is formed, the specific portions X of the second insulating film 52, the third insulating film 53, and the electrode layer 98 are sloped in correspondence with the upper surface 82B of the second insulator 82, instead of forming steps as described above. Accordingly, the electrode layer 99 will not be formed on steps. As a result, the electrode layer 99 has a relatively uniform thickness, thereby avoiding wire breakage that would be caused by a local reduction in the thickness of the electrode layer 99.

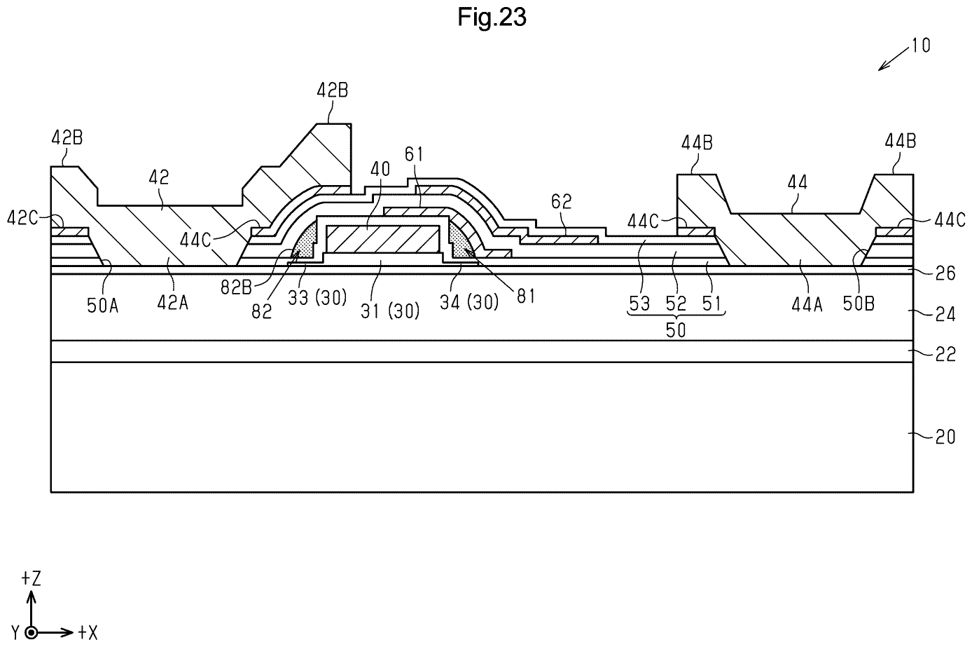

In the following manufacturing step illustrated in FIG. 23, the source electrode 42 and the drain electrode 44 are formed by selectively etching the electrode layer 98 using a mask (not shown) formed on the electrode layer 98. The nitride semiconductor device 10 shown in FIG. 4 is manufactured through the steps described above.

### Operation

As shown in FIG. 5, the nitride semiconductor device 10 includes the gate structure G, the first insulating film 51, and the first field plate electrode 61. The gate structure G includes the gate layer 30, and the gate electrode formed on the gate layer 30. The first insulating film 51 covers the electron supply layer 26 and the gate structure G. The first field plate electrode 61 is formed on the first insulating film 51. The first field plate electrode 61 includes a portion located between the first side wall G1 of the gate structure G and the drain electrode 44. The first side wall G1 of the gate structure G faces the first field plate electrode 61 with the first insulating film 51 located in between.

In this case, the first field plate electrode 61 covering the first side wall G1 of the gate structure G mitigates concentration of the electric field in the vicinity of the first side wall G1 of the gate structure G; particularly, in the vicinity of the gate layer 30. However, in a structure in which the first side wall G1 of the gate structure G faces the first field plate electrode 61 with the first insulating film 51 located in between, a parasitic capacitance C2 may form between the first side wall G1 of the gate structure G and the first field plate electrode 61. The parasitic capacitance C2 formed between the gate structure G and the first field plate electrode 61 may adversely affect the switching responsiveness or the like of the nitride semiconductor device 10.

In this respect, in the nitride semiconductor device 10, the first insulator 81 is formed to face the first side wall G1 of the gate structure G with the first insulating film 51 located in between. Accordingly, the first side wall G1 of the gate structure G faces the first field plate electrode 61 with the first insulating film 51 and the first insulator 81 located in between. In this case, the first insulating film 51 disposed between the first side wall G1 of the gate structure G and the first field plate electrode 61 increases a distance from the first side wall G1 of the gate structure G to the first field plate electrode 61. As a result, the distance between the electrodes that form the parasitic capacitance C2 is relatively large, thereby reducing the parasitic capacitance C2.

### Advantages

(1) The nitride semiconductor device 10 includes the substrate 20, the electron transit layer 24, the electron supply layer 26, the gate structure G, the first insulating film 51, the source electrode 42, the drain electrode 44, the first field plate electrode 61, and the first insulator 81. The electron transit layer 24 is formed on the substrate 20. The electron supply layer 26 is formed on the electron transit layer 24. The gate structure G includes the gate layer 30 formed on part of the electron supply layer 26, and the gate electrode formed on the gate layer 30. The first insulating film 51 covers the electron supply layer 26 and the gate structure G. The source electrode 42 is in contact with the electron supply layer 26 in the source opening 50A formed in the first insulating film 51. The drain electrode 44 is in contact with the electron supply layer 26 in the drain opening 50B formed in the first insulating film 51. The first field plate electrode 61 is formed on the first insulating film 51 and includes a portion located between the first side wall G1 of the gate structure G and the drain electrode 44. The first insulator 81 is formed between the first insulating film 51 and the first field plate electrode 61 and faces the first side wall G1 of the gate structure G with the first insulating film 51 located in between. The first side wall G1 of the gate structure G and the first field plate electrode 61 face each other with the first insulating film 51 and the first insulator 81 located in between.

In this case, the first insulating film 51 disposed between the first side wall G1 of the gate structure G and the first field plate electrode 61 increases a distance from the first side wall G1 of the gate structure G to the first field plate electrode 61. This reduces the parasitic capacitance C2 formed between the first side wall G1 of the gate structure G and the first field plate electrode 61, thereby limiting adverse effects of the parasitic capacitance C2 on the switching responsiveness or the like.
(2) The gate layer 30 includes the ridge 31 and the drain-side extension 34. The ridge 31 is in contact with the electron supply layer 26, and includes the upper surface 31A on which the gate electrode 40 is formed. The drain-side extension 34 is thinner than the ridge 31, and extends from the ridge 31 toward the drain electrode 44.

In this case, the drain-side extension 34 restricts concentration of the electric field at the bottom corner of the ridge 31 located relatively close to the drain electrode 44. Also, the drain-side extension 34 serves as a gate field plate electrode that mitigates concentration of the electric field underneath the drain-side extension 34. This avoids increases in a drain leakage current due to a localized concentration of the electric field.
(3) The gate layer 30 includes the drain-side extension 34 that is thinner than the ridge 31, and extends from the ridge 31 toward the drain electrode 44. The gate layer 30 includes the source-side extension 33 that is thinner than the ridge 31, and extends from the ridge 31 toward the source electrode 42.

In this case, when a forward voltage is applied between the gate and the source, the drain-side extension 34 mitigates the electric field intensity at the bottom corner of the ridge 31 located relatively close to the drain electrode 44. In the same manner, the source-side extension 33 mitigates the electric field intensity at the bottom corner of the ridge 31 located relatively close to the source electrode 42. In addition, the drain-side extension 34 and the source-side extension 33 each share part of the electric field, thereby reducing the electric field intensity at the gate electrode 40. This may improve the breakdown withstand capability of the gate.
(4) The first insulator 81 is disposed within the range R1, in which the gate layer 30 is formed. The first field plate electrode 61 includes a portion located closer to the drain electrode 44 than the first insulator 81 is. In other words, the drain-side extension 34 includes a distal end located closer to the drain electrode 44 than the first insulator 81 is. The first field plate electrode 61 includes a portion located on the distal end of the drain-side extension 34.

The first insulator 81 separates the portion of the first field plate electrode 61 located on the first insulator 81 from the electron supply layer 26. This may diminish the effect of the first field plate electrode 61 that mitigates concentration of the electric field at a portion of the electron supply layer 26 located immediately below the first insulator 81. Nonetheless, the gate layer 30, particularly, the drain-side extension 34, is located directly below the first insulator 81. Accordingly, the drain-side extension 34 mitigates concentration of the electric field at the portion of the electron supply layer 26 located immediately below the first insulator 81. In this manner, even when the first insulator 81 is formed, the electric field concentration is reduced at a portion of the electron supply layer 26 located immediately below the first insulator 81.
(5) The first field plate electrode 61 includes the portion 61C located closer to the drain electrode 44 than the drain-side extension 34 is in the X-axis direction. In this case, between the gate electrode 40 and the drain electrode 44, a region in which the drain-side extension 34 mitigates concentration of the electric field partially overlaps a region in which the first field plate electrode 61 mitigates concentration of the electric field. Accordingly, the electric field concentration is reduced in a relatively large continuous region between the gate electrode 40 and the drain electrode 44. This may improve the breakdown withstand capability of the drain.
(6) The first field plate electrode 61 includes the upper-surface facing part 61D that faces the gate electrode 40 in the Z-axis direction, and the side-surface facing part 61E that faces the first side wall G1 of the gate structure G. The side-surface facing part 61E is greater in area than the upper-surface facing part 61D.

The upper-surface facing part 61D of the first field plate electrode 61 may cause formation of the parasitic capacitance C1 between the upper-surface facing part 61D and the gate electrode 40. Further, the side-surface facing part 61E of the first field plate electrode 61 may cause formation of the parasitic capacitance C2 between the side-surface facing part 61E and the first side wall G1 of the gate structure G. When the side-surface facing part 61E is greater in area than the upper-surface facing part 61D, a ratio of the parasitic capacitance C2 to a sum of the parasitic capacitance C1 and the parasitic capacitance C2 is relatively high. Therefore, this structure further enhances the above-described advantage (1) of reducing the parasitic capacitance C2. That is, the parasitic capacitance caused by the first field plate electrode 61 is further reduced.
(7) The nitride semiconductor device 10 further includes the second insulating film 52 and the second insulator 82. The second insulating film 52 covers the first insulating film 51 and the first field plate electrode 61. The second insulator 82 is formed between the first insulating film 51 and the second insulating film 52, and faces the second side wall G2 of the gate structure G with the first insulating film 51 located in between. The second insulator 82 includes the upper surface 82B sloped toward the electron supply layer 26 as the upper surface 82B extends from the gate structure G toward the source electrode 42. The first field plate electrode 61 is selectively formed at a position located closer to the drain electrode 44 than the second insulator 82 is.

In this case, when etching the electrode layer 96 to form the first field plate electrode 61, as described with reference to the manufacturing step illustrated in FIG. 17, unwanted residue will not remain along the second side wall G2 of the gate structure G (refer to FIG. 24). Unwanted residue of the electrode layer 96 may act as a floating electrode, which destabilizes the gate voltage and adversely affects the gate life. Therefore, minimizing unwanted residues may contribute to stabilization of the gate voltage and improvement of the gate life.
(8) The nitride semiconductor device 10 further includes third insulating film 53 and the second field plate electrode 62. The third insulating film 53 covers the second insulating film 52. The second field plate electrode 62 is formed between the second insulating film 52 and the third insulating film 53, and is selectively formed at a position located closer to the drain electrode 44 than the second insulator 82 is. The second field plate electrode 62 includes a portion located on the first field plate electrode 61, and a portion located closer to the drain electrode 44 than the first field plate electrode 61 is.

With the structure in which the second field plate electrode 62 is not located above the second side wall G2 of the gate structure G, when etching the electrode layer 97 to form the second field plate electrode 62, unwanted residue may remain in the same manner as when forming the first field plate electrode 61. However, the second insulator 82 has the same advantage of when forming the first field plate electrode 61, so that unwanted residue of the second field plate electrode 62 will not remain.
(9) The source electrode 42 includes the source extension 42B disposed on the first insulating film 51. The source extension 42B includes a portion located on the second insulator 82. In this case, the source extension 42B may have a relatively uniform thickness. This avoids wire breakage of the source electrode 42 that would be caused by a local reduction in the thickness of the source extension 42B.
(10) The upper surface 82B of the second insulator 82 includes a curved surface projecting in a direction extending from the gate structure G toward the source electrode 42. In this case, when forming the electrode layer 96 so as to form the first field plate electrode 61, the sloped part 96A may have a relatively smooth shape in correspondence with the upper surface 82B of the second insulator 82. This further enhances the above-described advantages (6) to (8).
(11) The upper surface 81B of the first insulator 81 is sloped toward the electron supply layer 26 as the upper surface 81B extends from the gate structure G toward the drain electrode 44. Preferably, the upper surface 81B of the first insulator 81 includes a curved surface projecting in a direction extending from the gate structure G toward the drain electrode 44.

In this case, a portion of the first field plate electrode 61 located on the first insulator 81 is inclined relative to the first side wall G1, instead of forming steps in correspondence with the first side wall G1 of the gate structure G. Therefore, as a result of an advantage similar to the above-described advantage (8), the first field plate electrode 61 has a relatively uniform thickness. This avoids wire breakage of the first field plate electrode 61 that would be caused by a local reduction in the thickness of the portion of the first field plate electrode 61 located on the first insulator 81.
(12) The first insulator 81 is composed of SiO₂. Further, the second insulator 82 is composed of SiO₂. With SiO₂, the surface shapes may be readily controlled during film formation. Accordingly, when etching a SiO₂ layer to form the first insulator 81 and the second insulator 82, the upper surface 81B of the first insulator 81 and the upper surface 82B of the second insulator 82 may be readily formed into a desired shape, such as a slope extending in a specified direction.

### Modified Examples

The nitride semiconductor device 10 is not limited to a HEMT that uses GaN, and may be a nitride semiconductor device that uses other types of nitride semiconductor.

The first insulator 81 may include a portion located on the ridge 31. Furthermore, the second insulator 82 may include a portion located on the ridge 31.

Various examples described in this specification may be combined as long as there is no technical contradiction.

In the present disclosure, the term “on” includes the meaning of “above” in addition to the meaning of “on” unless clearly described otherwise in the context. Accordingly, for example, a phrase such as “first element formed on second element” may mean that the first element is directly located on the second element in one embodiment and that the first element is located above the second element without contacting the second element in another embodiment. Therefore, the term “on” does not exclude a structure in which another element is disposed between the first element and the second element.

The Z-axis direction as referred to in this specification does not have to be the vertical direction, and does not have to exactly coincide with the vertical direction. Accordingly, in the various structures of the present disclosure, “up” and “down” in the Z-axis direction as referred to in this specification are not limited to “up” and “down” in the vertical direction. For example, the X-axis direction or the Y-axis direction may be the vertical direction.

### CLAUSES

Technical concepts that can be understood from the present disclosure will now be described. Reference characters used in the described embodiment are added to corresponding elements in the clauses to aid understanding without any intention to impose limitations on these elements. The reference characters are given as examples to aid understanding, and are not intended to limit elements to the elements denoted by the reference characters.

### Clause 1

A nitride semiconductor device (10), including:
a substrate (20);
an electron transit layer (24) formed on the substrate (20) and composed of a nitride semiconductor;
an electron supply layer (26) formed on the electron transit layer (24) and composed of a nitride semiconductor having a larger band gap than the electron transit layer (24);
a gate structure (G) formed on part of the electron supply layer (26), the gate structure (G) including a gate layer (30) composed of a nitride semiconductor containing an acceptor impurity, and a gate electrode (40) formed on the gate layer (30);
a first insulating film (51) covering the electron supply layer (26) and the gate structure (G);
a source electrode (42) located at a side of the gate structure (G) in a first direction (X-axis direction), the source electrode (42) being in contact with the electron supply layer (26) in a source opening (50A) formed in the first insulating film (51);
a drain electrode (44) located at an other side of the gate structure (G) in the first direction (X-axis direction), the drain electrode (44) being in contact with the electron supply layer (26) in a drain opening (50B) formed in the first insulating film (51); a first field plate electrode (61) formed on the first insulating film (51) and including a portion located between the drain electrode (44) and a side wall (G1) of the gate structure (G) in the first direction (X-axis direction), the side wall (G1) being located relatively close to the drain electrode (44); and
a first insulator (81) formed between the first insulating film (51) and the first field plate electrode (61) and facing the side wall (G1) of the gate structure (G), which is located relatively close to the drain electrode (44), with the first insulating film (51) located in between in the first direction (X-axis direction),
in which the side wall (G1) of the gate structure (G), which is located relatively close to the drain electrode (44), and the first field plate electrode (61) face each other with the first insulating film (51) and the first insulator (81) located in between.

### Clause 2

The nitride semiconductor device (10) according to clause 1, in which the gate layer (30) includes
a ridge (31) in contact with the electron supply layer (26) and including an upper surface (31A) on which the gate electrode (40) is formed, and
a drain-side extension (34) extending from the ridge (31) toward the drain electrode (44) in the first direction (X-axis direction), the drain-side extension (34) being thinner than the ridge (31).

### Clause 3

The nitride semiconductor device (10) according to clause 2, in which
in plan view as viewed in a thickness-wise direction of the substrate (20), the first insulator (81) is disposed within a range (R) in which the gate layer (30) is formed, and
the first field plate electrode (61) includes a portion located closer to the drain electrode (44) than the first insulator (81) is in the first direction (X-axis direction).

### Clause 4

The nitride semiconductor device (10) according to clause 2 or 3, in which
the drain-side extension (34) includes a distal end located closer to the drain electrode (44) than the first insulator (81) is in the first direction (X-axis direction), and
the first field plate electrode (61) includes a portion located on the distal end of the drain-side extension (34).

### Clause 5

The nitride semiconductor device (10) according to clause 4, in which the first field plate electrode (61) includes a portion (61C) located closer to the drain electrode (44) than the drain-side extension (34) is in the first direction (X-axis direction).

### Clause 6

The nitride semiconductor device (10) according to any one of clauses 1 to 5, in which
the first field plate electrode (61) includes an upper-surface facing part (61D) facing the gate electrode (40) in a thickness-wise direction (Z-axis direction), and a side-surface facing part (61E) facing the side wall (G1) of the gate structure (G), which is located relatively close to the drain electrode (44), in the first direction (X-axis direction), and
the side-surface facing part (61E) is greater in area than the upper-surface facing part (61D).

### Clause 7

The nitride semiconductor device (10) according to any one of clauses 1 to 6, in which the first insulator (81) includes an upper surface (81B) sloped toward the electron supply layer (26) as the upper surface (81B) extends from the gate structure (G) toward the drain electrode (44).

### Clause 8

The nitride semiconductor device (10) according to clause 7, in which the upper surface (81B) of the first insulator (81) includes a curved surface projecting in a direction extending from the gate structure (G) toward the drain electrode (44).

### Clause 9

The nitride semiconductor device (10) according to any one of clauses 1 to 8, in which the first insulator (81) is composed of SiO₂.

### Clause 10

The nitride semiconductor device (10) according to any one of clauses 1 to 9, in further including:
a second insulating film (52) covering the first insulating film (51) and the first field plate electrode (61); and
a second insulator (82) formed between the first insulating film (51) and the second insulating film (52) and facing an other side wall (G2) of the gate structure (G) with the first insulating film (51) located in between in the first direction (X-axis direction), the other side wall (G2) being located relatively close to the source electrode (42), in which
the second insulator (82) includes an upper surface (82B) sloped toward the electron supply layer (26) as the upper surface (82B) extends from the gate structure (G) toward the source electrode (42), and
the first field plate electrode (61) is selectively formed at a position located closer to the drain electrode (44) than the second insulator (82) is in the first direction (X-axis direction).

### Clause 11

The nitride semiconductor device (10) according to clause 10, in which the upper surface (82B) of the second insulator (82) includes a curved surface projecting in a direction extending from the gate structure (G) toward the source electrode (42).

### Clause 12

The nitride semiconductor device (10) according to clause 10 or 11, further comprising:
a third insulating film (53) covering the second insulating film (52); and
a second field plate electrode (62) formed between the second insulating film (52) and the third insulating film (53) and selectively formed at a position located closer to the drain electrode (44) than the second insulator (82) is in the first direction (X-axis direction),
in which the second field plate electrode (62) includes a portion located on the first field plate electrode (61), and a portion located closer to the drain electrode (44) than the first field plate electrode (61) is in the first direction (X-axis direction).

### Clause 13

The nitride semiconductor device (10) according to any one of clauses 10 to 12, in which
the source electrode (42) includes a source extension (42B) disposed on the first insulating film (51), and
the source extension (42B) includes a portion located on the second insulator (82).

### Clause 14

The nitride semiconductor device (10) according to any one of clauses 10 to 13, in which the second insulator (82) is composed of SiO₂.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A nitride semiconductor device, comprising:
a substrate;
an electron transit layer formed on the substrate and composed of a nitride semiconductor;
an electron supply layer formed on the electron transit layer and composed of a nitride semiconductor having a larger band gap than the electron transit layer;
a gate structure formed on part of the electron supply layer, the gate structure including a gate layer composed of a nitride semiconductor containing an acceptor impurity, and a gate electrode formed on the gate layer;
a first insulating film covering the electron supply layer and the gate structure;
a source electrode located at a side of the gate structure in a first direction, the source electrode being in contact with the electron supply layer in a source opening formed in the first insulating film;
a drain electrode located at an other side of the gate structure in the first direction, the drain electrode being in contact with the electron supply layer in a drain opening formed in the first insulating film;
a first field plate electrode formed on the first insulating film and including a portion located between the drain electrode and a side wall of the gate structure in the first direction, the side wall being located relatively close to the drain electrode; and
a first insulator formed between the first insulating film and the first field plate electrode and facing the side wall of the gate structure, which is located relatively close to the drain electrode, with the first insulating film located in between in the first direction,
wherein the side wall of the gate structure, which is located relatively close to the drain electrode, and the first field plate electrode face each other with the first insulating film and the first insulator located in between.

2. The nitride semiconductor device according to claim 1, wherein
in plan view as viewed in a thickness-wise direction of the substrate, the first insulator is disposed within a range in which the gate layer is formed, and
the first field plate electrode includes a portion located closer to the drain electrode than the first insulator is in the first direction.

3. The nitride semiconductor device according to claim 2, wherein
the gate layer includes
a ridge in contact with the electron supply layer and including an upper surface on which the gate electrode is formed, and
a drain-side extension extending from the ridge toward the drain electrode in the first direction, the drain-side extension being thinner than the ridge,
the drain-side extension includes a distal end located closer to the drain electrode than the first insulator is in the first direction, and
the first field plate electrode includes a portion located on the distal end of the drain-side extension.

4. The nitride semiconductor device according to claim 3, wherein the first field plate electrode includes a portion located closer to the drain electrode than the drain-side extension is in the first direction.

5. The nitride semiconductor device according to claim 1, wherein
the first field plate electrode includes an upper-surface facing part facing the gate electrode in a thickness-wise direction, and a side-surface facing part facing the side wall of the gate structure, which is located relatively close to the drain electrode, in the first direction, and
the side-surface facing part is greater in area than the upper-surface facing part.

6. The nitride semiconductor device according to claim 1, wherein the first insulator includes an upper surface sloped toward the electron supply layer as the upper surface extends from the gate structure toward the drain electrode.

7. The nitride semiconductor device according to claim 6, wherein the upper surface of the first insulator includes a curved surface projecting in a direction extending from the gate structure toward the drain electrode.

8. The nitride semiconductor device according to claim 1, wherein the first insulator is composed of SiO₂.

9. The nitride semiconductor device according to claim 1, further comprising:
a second insulating film covering the first insulating film and the first field plate electrode; and
a second insulator formed between the first insulating film and the second insulating film and facing an other side wall of the gate structure with the first insulating film located in between in the first direction, the other side wall being located relatively close to the source electrode, wherein
the second insulator includes an upper surface sloped toward the electron supply layer as the upper surface extends from the gate structure toward the source electrode, and
the first field plate electrode is selectively formed at a position located closer to the drain electrode than the second insulator is in the first direction.

10. The nitride semiconductor device according to claim 9, wherein the upper surface of the second insulator includes a curved surface projecting in a direction extending from the gate structure toward the source electrode.

11. The nitride semiconductor device according to claim 9, further comprising:
a third insulating film covering the second insulating film; and
a second field plate electrode formed between the second insulating film and the third insulating film and selectively formed at a position located closer to the drain electrode than the second insulator is in the first direction,
wherein the second field plate electrode includes a portion located on the first field plate electrode, and a portion located closer to the drain electrode than the first field plate electrode is in the first direction.

12. The nitride semiconductor device according to claim 9, wherein
the source electrode includes a source extension disposed on the first insulating film, and
the source extension includes a portion located on the second insulator.

13. The nitride semiconductor device according to claim 9, wherein the second insulator is composed of SiO₂.
